(19) United States
(12) Patent Application Publication
(10) Pub. No.: US 2024/0372050 A1
(43) Pub. Date: Nov. 7, 2024

(54) DISPLAY PANEL AND METHOD OF MANUFACTURING THE SAME, AND DISPLAY APPARATUS

(71) Applicant: BOE TECHNOLOGY GROUP CO., LTD., Beijing (CN)

(72) Inventors: Kai GUO, Beijing (CN); Weixing LIU, Beijing (CN); Yuwei YAN, Beijing (CN); Meirong LU, Beijing (CN); Zhiqiang XU, Beijing (CN); Chunfang ZHANG, Beijing (CN); Wanpeng TENG, Beijing (CN); Jintao PENG, Beijing (CN); Xinxing WANG, Beijing (CN)

(73) Assignee: BOE TECHNOLOGY GROUP CO., LTD., Beijing (CN)

(21) Appl. No.: 18/774,927

(22) Filed: Jul. 17, 2024

Related U.S. Application Data
(63) Continuation of application No. PCT/CN2023/083166, filed on Mar. 22, 2023.

(51) Int. Cl. H01L 33/58; H01L 25/075; H01L 33/00; H01L 33/50; H01L 33/62

(52) U.S. Cl. CPC H01L 33/58; H01L 25/0753; H01L 33/005; H01L 33/505; H01L 33/62; H01L 2933/0041; H01L 2933/0058; H01L 2933/0066

(57) ABSTRACT

A display panel includes a driving backplane, an optical device layer, an adhesive layer and an optical conversion layer. The optical device layer includes optical devices each including a buffer layer and at least one light emitting unit. The buffer layer includes a first surface and a second surface. The first surface is farther away from the driving backplane than the second surface. The light-emitting unit is located on a side of the second surface away from the first surface. A buffer layer of at least one optical device further includes a side surface for connecting a first surface and a second surface. The side surface intersects with the first surface to form a first acute angle, and the side surface intersects with the second surface to form a first obtuse angle. A refractive index of the adhesive layer is less than a refractive index of the buffer layer.

### CROSS-REFERENCE TO RELATED APPLICATION

This application is a Bypass Continuation application of International Patent Application No. PCT/CN2023/083166, filed on Mar. 22, 2023, which is incorporated herein by reference in its entirety.

### TECHNICAL FIELD

The present disclosure relates to the field of display technologies, and in particular, to a display panel, a method of manufacturing a display panel, and a display apparatus.

### BACKGROUND

With the development of technology and display requirements, mini light-emitting diodes (mini LEDs) are the future development trend of display devices, which have unparalleled advantages (such as ultra-high contrast, ultra-high color gamut, high luminous efficiency, high brightness, low energy consumption, etc.) over liquid crystal displays and organic electroluminescent display panels.

### SUMMARY

In an aspect, a display panel is provided. The display panel includes a driving backplane, an optical device layer, an adhesive layer and an optical conversion layer. The optical device layer is located on a side of the driving backplane. The optical device layer includes a plurality of optical devices. Each of the plurality of optical devices includes a buffer layer and at least one light-emitting unit. The buffer layer includes a first surface and a second surface, and the first surface is farther away from the driving backplane than the second surface. The light-emitting unit is located on a side of the second surface away from the first surface. One light-emitting unit is located in one sub-pixel region. A buffer layer of an optical device of at least one of the plurality of optical devices further includes a side surface, the side surface intersects with a first surface of the buffer layer of the optical device to form a first acute angle, and the side surface intersects with a second surface of the buffer layer of the optical device to form a first obtuse angle. The optical conversion layer is located on a side of the optical device layer away from the driving backplane. The adhesive layer is located between the buffer layer of each of the plurality of optical devices of the optical device layer and the optical conversion layer. The adhesive layer is in contact with the first surface of the buffer layer of each of the plurality of optical devices. A refractive index of the adhesive layer is less than a refractive index of the buffer layer of each of the plurality of optical devices.

In some embodiments, a value α1 of the first acute angle satisfies:

$$α 1 < 90 ° - arc sin \frac{1}{n 1} ,$$

where n1 is the refractive index of the buffer layer.

In some embodiments, the display panel further includes a light-shielding portion, the light-shielding portion is located on a side of the first surface proximate to the driving backplane, and an orthographic projection of the light-shielding portion on the driving backplane at least partially overlaps with an orthographic projection of the side surface on the driving backplane.

In some embodiments, the light-shielding portion includes a first light-shielding portion, the first light-shielding portion is located on the side surface, and the first light-shielding portion is in contact with the side surface.

In some embodiments, a surface of the first light-shielding portion proximate to the driving backplane is flush with the second surface; and/or, in a first direction, an orthographic projection of a surface of the first light-shielding portion away from the buffer layer on the driving backplane overlaps with a boundary of an orthographic projection of the first surface on the driving backplane, the first direction being parallel to the driving backplane.

In some embodiments, in a direction away from the driving backplane, the light-emitting unit includes: a first electrode, a first semiconductor layer electrically connected to the first electrode, a light-generating layer, and a second semiconductor layer. The light-emitting unit further includes a second electrode electrically connected to the second semiconductor layer. The second electrode is located on a side of the second semiconductor layer proximate to the driving backplane. The light-shielding portion further includes a second light-shielding portion. The second light-shielding portion is located on a side of the second semiconductor layer away from the second electrode.

In some embodiments, a part of the second light-shielding portion proximate to the buffer layer of the optical device is in contact with a part of the side surface of the buffer layer of the optical device proximate to the second surface of the buffer layer of the optical device; and/or, a boundary of an orthographic projection of the second light-shielding portion on the driving backplane exceeds a boundary of an orthographic projection the first surface on the driving backplane.

In some embodiments, a width L1 of the second light-shielding portion in a first direction satisfies:

$$L 1 = \frac{D 1}{sin α 1 \times cos α 1} ,$$

where α1 is a value of the first acute angle, D1 is a thickness of the buffer layer, and the first direction is parallel to the driving backplane.

In some embodiments, the driving backplane includes a base substrate and a plurality of connection electrodes located on the base substrate. Connection electrodes among the plurality of connection electrodes are electrically connected to a light-emitting unit. The light-shielding portion further includes a third light-shielding portion, and the third light-shielding portion is located on a side of the base substrate proximate to the buffer layer.

In some embodiments, an orthographic projection, on the base substrate, of a part of the third light-shielding portion proximate to the light-emitting unit is in contact with a boundary of an orthographic projection, on the base substrate, of the second surface; and/or, a boundary of an orthographic projection of the third light-shielding portion on the base substrate exceeds a boundary of an orthographic projection of the first surface on the base substrate.

In some embodiments, a width L2 of the third light-shielding portion in a first direction satisfies:

$$L 2 = \frac{D 1 + D 2}{sin α 1 \times cos α 1} - \frac{D 2 \times cos α 1}{sin α 1} ,$$

where α1 is a value of the first acute angle, D1 is a thickness of the buffer layer, D2 is a thickness of the light-emitting unit, and the first direction is parallel to the driving backplane.

In some embodiments, the optical conversion layer includes a blocking portion and a plurality of color conversion portions. The blocking portion separates the plurality of color conversion portions. An orthographic projection of a color conversion portion on the driving backplane at least partially overlaps with an orthographic projection of a light-emitting unit on the driving backplane. The color conversion portions include a first-type color conversion portion and a second-type color conversion portion. The first-type color conversion portion is configured to convert a color of light emitted by a light-emitting unit into a target color. The second-type color conversion portion is configured to directly transmit light emitted by a light-emitting unit.

In some embodiments, the orthographic projection of the color conversion portion on the driving backplane covers the orthographic projection of the light-emitting unit on the driving backplane.

In some embodiments, the display panel further includes a color filter layer, and the color filter layer is located on a side of the optical conversion layer away from the driving backplane. The color filter layer includes a plurality of filter units and a black matrix, and the black matrix separates the plurality of the filter units. An orthographic projection of a filter unit on the driving backplane at least partially overlaps with an orthographic projection of a light-emitting unit on the driving backplane.

In some embodiments, the orthographic projection of the filter unit on the driving backplane covers the orthographic projection of the light-emitting unit on the driving backplane.

In another aspect, a method of manufacturing a display panel is provided. The display panel has a plurality of sub-pixel regions. The method includes: providing a glass substrate; forming an optical conversion layer on the glass substrate; providing a sapphire substrate; forming a buffer mother-layer on the sapphire substrate, the buffer mother-layer being used for forming a plurality of buffer layers, each of the plurality of buffer layers including a first surface and a second surface; forming a plurality of light-emitting units on a side of the buffer mother-layer away from the sapphire substrate, so as to form an optical device mother-layer, one light-emitting unit being located in one sub-pixel region; providing a transfer substrate; bonding the light-emitting units in the optical device mother-layer to the transfer substrate; removing the sapphire substrate; forming a via hole in the buffer mother-layer, so as to form a side surface of each of at least one buffer layer of the plurality of buffer layers, wherein the side surface intersects with a first surface of each of the at least one buffer layer to form a first acute angle, and the side surface intersects with a second surface of each of the at least one buffer layer to form a first obtuse angle; providing an adhesive layer; adhering the optical conversion layer and the buffer mother-layer through the adhesive layer; removing the transfer substrate; cutting the optical device mother-layer to form an optical device layer including a plurality of optical devices, wherein at least one light-emitting unit of the plurality of light-emitting units and a buffer layer arranged opposite thereto constitute an optical device; and in the optical device, the first surface of the buffer layer is disposed on a side of the second surface away from the at least one light-emitting unit; providing a driving backplane; and electrically connecting the driving backplane and the light-emitting units in the optical devices.

In some embodiments, the method further includes: forming a first light-shielding portion on the side surface, an orthographic projection of the first light-shielding portion on the driving backplane covering an orthographic projection of the side surface on the driving backplane.

In some embodiments, in a direction away from the driving backplane, a light-emitting unit includes: a first electrode, a first electrode, a first semiconductor layer electrically connected to the first electrode, a light-generating layer, a second semiconductor layer; and the light-emitting unit further includes a second electrode electrically connected to the second semiconductor layer. The method further includes: forming a second light-shielding portion on a side, away from the second electrode, of a part of the second semiconductor layer exposed by the via hole, the second light-shielding portion being arranged along a peripheral direction of a second surface.

In some embodiments, the driving backplane includes a base substrate and a plurality of connection electrodes located on the base substrate; connection electrodes among the plurality of connection electrodes are electrically connected to a light-emitting unit; the method further includes: after the connection electrodes in the driving backplane are electrically connected to the light-emitting unit, forming a third light-shielding portion on the base substrate, wherein an orthographic projection of the third light-shielding portion on the base substrate is arranged along a peripheral direction of an orthographic projection of a second surface on the base substrate.

In yet another aspect, a display apparatus is provided. The display apparatus includes the display panel as described in any of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a structural diagram of a display panel, in accordance with some embodiments;

FIG. 3 is a structural diagram of the pixel region in FIG. 2;

FIG. 4 is a sectional diagram of a display panel, in accordance with some embodiments;

FIG. 5 is a graph showing a curve of brightness of a second sub-pixel region P2 changing with a distance in a direction A1, in accordance with some embodiments;

FIG. 6 is a graph showing a curve of brightness of a second sub-pixel region P2 changing with a distance in a direction A2, in accordance with some embodiments;

FIG. 7 is a graph showing a curve of brightness of a first sub-pixel region P1 changing with a distance in a direction A1, in accordance with some embodiments;

FIG. 8 is a graph showing a curve of brightness of a first sub-pixel region P1 changing with a distance in a direction A2, in accordance with some embodiments;

FIG. 9 is a sectional view of another display panel, in accordance with some embodiments;

FIG. 10 is a partial enlarged view of the region Q in FIG. 9;

FIG. 11 is a sectional view of yet another display panel, in accordance with some embodiments;

FIG. 12 is a sectional view of yet another display panel, in accordance with some embodiments;

FIG. 13 is a sectional view of yet another display panel, in accordance with some embodiments;

FIG. 14 is a partial enlarged view of the region W in FIG. 13;

FIG. 15 is another partial enlarged view of the region W in FIG. 13;

FIG. 16 is a sectional view of yet another display panel, in accordance with some embodiments;

FIG. 17 is a partial enlarged view of the region F in FIG. 16;

FIG. 18 is a sectional view of yet another display panel, in accordance with some embodiments;

FIG. 19 is a partial enlarged view of the region H in FIG. 18;

FIG. 20 is a sectional view of yet another display panel, in accordance with some embodiments;

FIG. 21 is a flow diagram of a method of manufacturing a display panel, in accordance with some embodiments;

FIG. 22 is a diagram showing structures corresponding to some steps in FIG. 21;

FIG. 23 is a diagram showing structures corresponding to some other steps in FIG. 21;

FIG. 24 is a diagram showing a structure corresponding to a step of a method of manufacturing a display panel, in accordance with some embodiments;

FIG. 25 is a diagram showing a structure corresponding to step S3 in FIG. 21;

FIG. 26 is a diagram showing another structure corresponding to a step of a method of manufacturing a display panel, in accordance with some embodiments; and

FIG. 27 is a diagram showing a structure corresponding to step S8 in FIG. 21.

### DETAILED DESCRIPTION

The technical solutions in embodiments of the present disclosure will be described clearly and completely with reference to the accompanying drawings. However, the described embodiments are merely some but not all of embodiments of the present disclosure. All other embodiments obtained on the basis of the embodiments of the present disclosure by a person of ordinary skill in the art shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, specific features, structures, materials, or characteristics described herein may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, features defined with “first” and “second” may explicitly or implicitly include one or more of the features. In the description of the embodiments of the present disclosure, the terms “a plurality of” “the plurality of” and “multiple” each mean two or more unless otherwise specified.

In the description of some embodiments, the term “connected” and its derivatives may be used. The term “connected” should be understood in a broad sense. For example, the term “connected” may represent a fixed connection, or a detachable connection, or a one-piece connection; alternatively, the term “connected” may represent a direct connection, or an indirect connection through an intermediate medium. The term “coupled”, for example, indicates that two or more components are in direct physical or electrical contact. The embodiments disclosed herein are not necessarily limited to the context herein.

The phrase “at least one of A, B and C” has the same meaning as the phrase “at least one of A, B or C”, both including following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

As used herein, the term “if” is, optionally, construed to mean “when” or “in a case where” or “in response to determining” or “in response to detecting”, depending on the context. Similarly, the phrase “if it is determined” or “if [a stated condition or event] is detected” is, optionally, construed to mean “in a case where it is determined” or “in response to determining” or “in a case where [the stated condition or event] is detected” or “in response to detecting [the stated condition or event]”, depending on the context.

The use of “applicable to” or “configured to” herein means an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or value beyond those stated.

The term such as “about”, “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

As used herein, the term such as “parallel” or “perpendicular” includes a stated condition and a condition similar to the stated condition, a range of the similar condition is within an acceptable range of deviation, and the acceptable range of deviation is determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; and the term “perpendicular” includes absolute perpendicularity and approximate perpendicularity, and an acceptable range of deviation of the approximate perpendicularity may also be, for example, a deviation within 5°.

It will be understood that, in a case where a layer or component is referred to as being on another layer or a substrate, it may be that the layer or component is directly on the another layer or substrate; or it may be that intermediate layer(s) exist between the layer or component and the another layer or substrate.

Exemplary embodiments are described herein with reference to sectional views and/or plan views as idealized exemplary drawings. In the accompanying drawings, thicknesses of layers and sizes of regions are enlarged for clarity. Variations in shape relative to the accompanying drawings due to, for example, manufacturing technologies and/or tolerances may be envisaged. Therefore, the exemplary embodiments should not be construed as being limited to the shapes of the regions shown herein, but including deviations due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

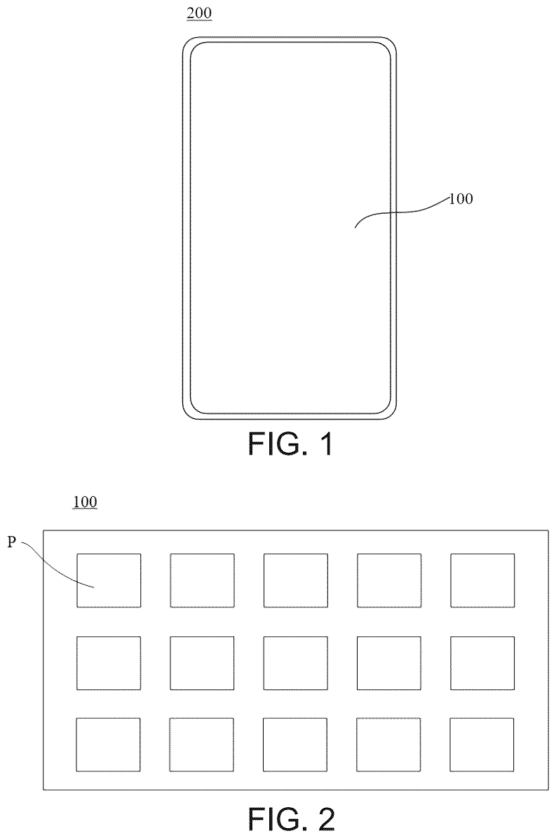

FIG. 1 is a structural diagram of a display apparatus, in accordance with some embodiments. Referring to FIG. 1, some embodiments of the present disclosure provide a display apparatus 200. The display apparatus 200 includes a display panel 100.

For example, the display apparatus 200 further includes a frame, a display driver integrated circuit (IC) and other electronic components.

For example, the display apparatus 200 is an electroluminescent display apparatus. The electroluminescent display apparatus may be a quantum dot light-emitting diode (QLED) display apparatus.

For example, the display apparatus 200 may be any device that can display images whether in motion (e.g., videos) or stationary (e.g., static images), and whether textual or graphical. More specifically, it is expected that the display apparatus in the embodiments may be implemented in or associated with a plurality of electronic devices. The plurality of electronic devices may include (but is not lim it to), for example, mobile telephones, wireless devices, personal data assistants (PDAs), hand-held or portable computers, GPS receivers/navigators, cameras, MP4 video players, video cameras, game consoles, watches, clocks, calculators, TV monitors, flat panel displays, computer monitors, car displays (e.g., odometer displays, etc.), navigators, cockpit controllers and/or displays, camera view displays (e.g., rear view camera displays in vehicles), electronic photos, electronic billboards or indicators, projectors, building structures, packagings and aesthetic structures (e.g., a display for an image of a piece of jewelry) etc.

The following description will be introduced by taking a display apparatus with mini-LED and quantum dot (QD) as an example.

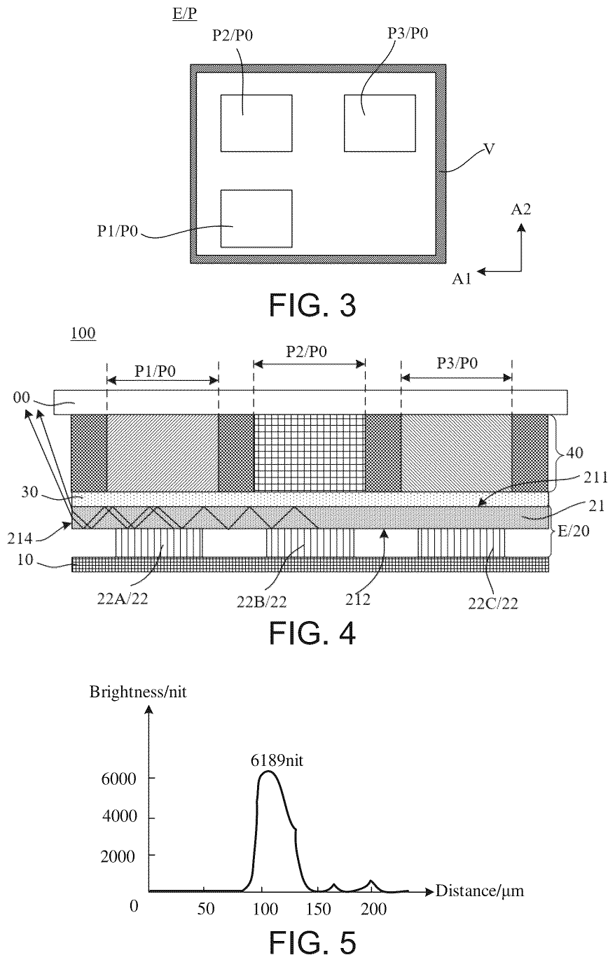

FIG. 2 is a structural diagram of a display panel, in accordance with some embodiments. FIG. 3 is a structural diagram of a pixel region in FIG. 2.

In some embodiments, referring to FIGS. 2 and 3, the display panel 100 has a plurality of pixel regions P. A pixel region P includes a plurality of sub-pixel regions P0. The plurality of sub-pixel regions P0 may include sub-pixel regions P0 that emit light of different colors.

For example, the plurality of sub-pixel regions P0 are divided into first sub-pixel regions P1, second sub-pixel regions P2 and third sub-pixel regions P3. For example, the first sub-pixel regions P1, the second sub-pixel regions P2 and the third sub-pixel regions P3 emit light of three primary colors. For example, the first sub-pixel regions P1 may emit red light, the second sub-pixel regions P2 may emit green light, and the third sub-pixel regions P3 may emit blue light.

FIG. 4 is a sectional view of a display panel, in accordance with some embodiments.

Referring to FIG. 4, the display panel 100 includes: a driving backplane 10, an optical device layer 20, an adhesive layer 30 and an optical conversion layer 40.

The optical device layer 20 is located on a side of the driving backplane 10. The optical device layer 20 includes a plurality of optical devices E. The optical device E includes a buffer layer 21 and at least one light-emitting unit 22, and one light-emitting unit 22 is located in one sub-pixel region P0.

The buffer layer 21 includes a first surface 211 and a second surface 212 that are arranged opposite to each other. The first surface 211 of the buffer layer 21 is farther away from the driving backplane 10 than the second surface 212. The light-emitting unit 22 is arranged on a side of the second surface 212 of the buffer layer 21 away from the first surface 211. That is, the light-emitting unit 22 is arranged on a side of the buffer layer 21 close to the driving backplane 10. Thus, it is convenient for the light-emitting unit 22 in optical device E to be bonded to the driving backplane 10.

Based on this, the driving backplane 10 may be used to drive the light-emitting unit(s) 22 in each optical device E to emit light, so that each sub-pixel region P0 of the display panel 100 emits light.

In some examples, the optical device E includes a light-emitting diode (LED) chip. The LED chip may be a micro LED or a mini LED.

The following description will be introduced by taking an example in which the optical device E is a mini LED.

In some examples, the light-emitting unit 22 may be a blue LED chip unit.

In some examples, one optical device E may include one light-emitting unit 22. In this case, one optical device E is located in one sub-pixel region P0. Three optical devices E can be set to be located in one pixel region P.

In some other examples, one optical device E may include three light-emitting units 22, and one light-emitting unit 22 is located in one sub-pixel region P0. The three light-emitting units 22 are respectively a first light-emitting unit 22A, a second light-emitting unit 22B and a third light-emitting unit 22C.

In this case, one optical device E is located in one pixel region P. Three light-emitting units 22 in one optical device E may be located in a first sub-pixel region P1, a second sub-pixel region P2 and a third sub-pixel region P3, respectively. For example, the first light-emitting unit 22A is located in the first sub-pixel region P1, the second light-emitting unit 22B is located in the second sub-pixel region P2, and the third light-emitting unit 22C is located in the third sub-pixel region P3.

In addition, when manufacturing the display panel 100, the optical devices E needs to be transferred, so as to be bonded to the driving backplane 10. Three light-emitting units 22 are assigned to one optical device E. When the number of light-emitting units 22 is constant, the number of optical devices E may be reduced and the size of the optical device E may be relatively increased. Based on this, in the process of transferring the optical devices E, the number of optical devices E that need to be transferred may be effectively reduced, thereby effectively reducing the number of transferring times, reducing process difficulty, and improving product yield.

The following description will be introduced by taking an example in which one optical device E may include three light-emitting units 22.

Three light-emitting units 22 may be generally formed on a substrate when forming any optical device E. For example, the light-emitting units 22 are formed on a sapphire substrate. A second semiconductor layer in the light-emitting unit 22 may be grown on the substrate. The growth of the second semiconductor layer in the light-emitting unit 22 on the substrate belongs to the growth of heterojunction. The lattice mismatch between the second semiconductor layer in the light-emitting unit 22 and the substrate is significant, making it difficult to directly fabricate a high-quality second semiconductor layer on the substrate.

Furthermore, the buffer layer 21 can be arranged between the second semiconductor layer in the light-emitting unit 22 and the substrate, so that the buffer layer 21 can be used to reduce defects caused by the growth of heterojunction, which is conducive to improving the quality of the second semiconductor layer.

In some examples, the material of the buffer layer 21 includes gallium nitride (GaN). In this case, the refractive index of the buffer layer 21 is approximately 2.4. However, the embodiments of the present disclosure are not limited thereto.

After the light-emitting units 22 are formed on the substrate, the substrate may be removed. Subsequently, the optical conversion layer 40 may be provided on a side of the buffer layer 21 in the optical device layer 20 away from the light-emitting unit 22. That is, the optical conversion layer 40 is formed on a light exit side of the optical device layer 20. In this case, the driving backplane 10 may be located on a side of the light-emitting units 22 away from the buffer layer 21.

Based on this, the driving backplane 10 in the display panel 100 can drive light emitting units 22 in different sub-pixel regions P0 to emit light of the same color. The light of the same color can develop light of different colors after being converted by the optical conversion layer 40. Based on this, the plurality of sub-pixel regions P0 in the display panel 100 can emit light of different colors. That is, in the display panel 100, the first sub-pixel regions P1 may emit red light, the second sub-pixel regions P2 may emit green light, and the third sub-pixel regions P3 may emit blue light, so that display images are formed.

How to use the optical conversion layer 40 to make the plurality of sub-pixel regions P0 emit different light will be described in detail in the following embodiments with reference to the accompanying drawings.

In addition, the adhesive layer 30 may be provided between the buffer layer 21 of the optical device layer 20 and the optical conversion layer 40. A surface of the adhesive layer 30 is in contact with the first surface 211 of the buffer layer 21, and another surface of the adhesive layer 30 is in contact with the optical conversion layer 40. Thus, the adhesive layer 30 is used to fix the optical device layer 20 and the optical conversion layer 40.

In some examples, the adhesive layer 30 may be a bonding adhesive layer. For example, the adhesive layer 30 may be made of benzocyclobutene (BCB). In this case, the refractive index of the adhesive layer 30 is approximately 1.56. However, the embodiments of the present disclosure are not limited thereto.

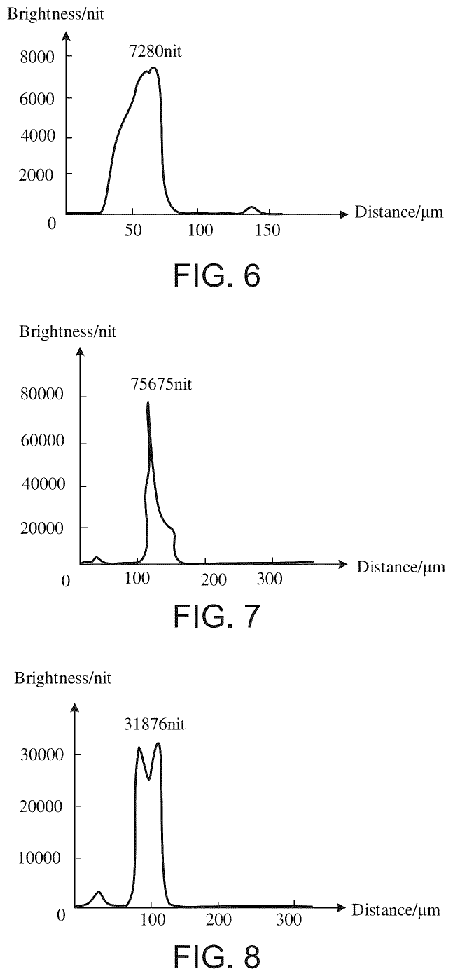

FIG. 5 is a graph showing a curve of brightness of a second sub-pixel region P2 changing with a distance in a direction A1, in accordance with some embodiments. FIG. 6 is a graph showing a curve of brightness of a second sub-pixel region P2 changing with a distance in a direction A2, in accordance with some embodiments. FIG. 7 is a graph showing a curve of brightness of a first sub-pixel region P1 changing with a distance in the direction A1, in accordance with some embodiments. FIG. 8 is a graph showing a curve of brightness of a first sub-pixel region P1 changing with a distance in the direction A2, in accordance with some embodiments. Here, the origin of the coordinate system in FIGS. 5 to 8 may be the center of the sub-pixel region.

However, the inventors of the present disclosure found through research that, as shown in FIG. 4, before the optical device layer 20 provided in the display panel 100 is bonded to the driving backplane 10, the optical device layer 20 is subjected to laser cutting to form the plurality of optical devices E. Subsequently, the cut independent optical devices E are bonded to the driving backplane 10. During the cutting process, cutting surfaces in the display panel 100 are rough. The buffer layer 21 will be cut during the cutting process, and a vertical surface 214 for connecting the first surface 211 and the second surface 212 will be formed in the buffer layer 21. Since the vertical surface 214 of the buffer layer 21 is formed by cutting the buffer layer 21, the vertical surface 214 will be rough.

Based on the above structure, as shown in FIGS. 4 and 5 to 8, in the display panel 100, since the refractive index of the adhesive layer 30 is less than the refractive index of the buffer layer 21, when part of light emitted by the light-emitting unit 22 is incident on the adhesive layer 30 passing through the buffer layer 21, the part of light will be totally reflected at an interface between the buffer layer 21 and the adhesive layer 30, and will be totally reflected and transmitted within the buffer layer 21 until it exits from a position where the edge of the buffer layer 21 is rough (the vertical surface 214) toward the optical conversion layer 40. Based on this, part of the light emitted by the light-emitting unit 22 will exist at the edge V of the optical device E (as shown in FIG. 3). This problem will not only affect the brightness of the light-emitting unit 22 in the optical device E, but also cause the light leakage problem at the edge V of the optical device E, which affects the quality of the image displayed by the display panel 100.

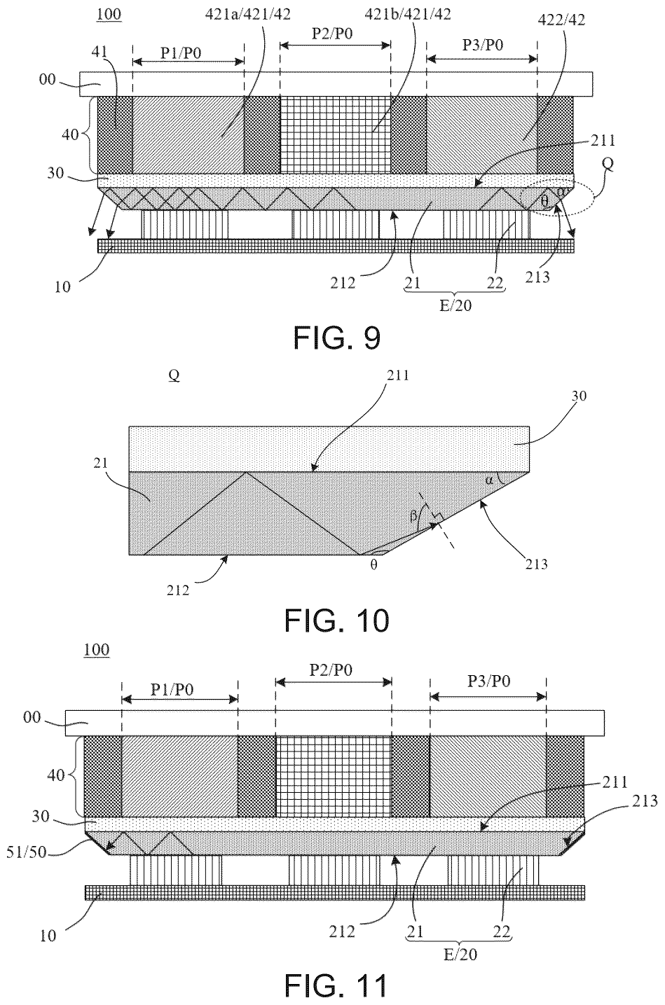

FIG. 9 is a sectional view of another display panel, in accordance with some embodiments. In FIG. 9, only one optical device E in the optical device layer 20 is taken as an example for illustration. It can be understood that in the display panel 100, gaps are provided between adjacent optical devices E to facilitate laser cutting of the optical device layer 20 to form the plurality of optical devices E during the manufacturing process.

In the display panel 100 provided in the embodiments of the present disclosure, referring to FIG. 9, the vertical surface 214 (as shown in FIG. 4) can be removed from the buffer layer 21 in at least one optical device E. The buffer layer 21 further includes a side surface 213. A part of the side surface 213 proximate to the first surface 211 intersects with and is connected to the first surface 211, and the side surface 213 intersects with the first surface 211 to form a first acute angle α. A part of the side surface 213 proximate to the second surface 212 is connected to the second surface 212, and the side surface 213 intersects with the second surface 212 to form a first obtuse angle θ. The first surface 211 is farther away from the driving backplane 10 than the second surface 212.

In this case, the side surface 213 of the buffer layer 21 in the optical device E is approximately facing the driving backplane 10, so that an inverted triangle structure may be formed at the edge of the buffer layer 21 in the optical device E.

In this way, when part of the light emitted by the light-emitting unit 22 undergoes total reflection at the interface between the buffer layer 21 and the adhesive layer 30 and undergoes total reflection transmission in the buffer layer 21 until it is transmitted to the side surface 213 of the buffer layer 21 and exits, since the side surface 213 is approximately facing the driving backplane 10, the probability of light directed toward the driving backplane 10 through the side surface 213 may be increased, which is conducive to reducing the probability of light directed toward the optical conversion layer 40 and ameliorating the light leakage at the edge of the optical device E. As a result, the quality of images displayed on the display panel 100 is improved.

The inventors of the present disclosure found through research that, the light leakage amount of the light-emitting unit 22 in the first sub-pixel region P1 for emitting red light in the light-emitting device E reaches 23.5%, and the light leakage amount of the light-emitting unit 22 in second sub-pixel region P2 for emitting green light in the light-emitting device E reaches 13.3%.

The light leakage amount of the light-emitting unit 22 in the first sub-pixel region P1 for emitting red light in the light-emitting device E and the light leakage amount of the light-emitting unit 22 in the second sub-pixel region P2 of the light-emitting device E for emitting green light are high.

In some examples, the buffer layer 21 in one optical device E in the display panel 100 and further includes a side surface 213 for connecting the first surface 211 and the second surface 212, the side surface 213 intersects with the first surface 211 to form a first acute angle α, and the side surface 213 intersects with the second surface 212 to form a first obtuse angle θ.

For example, the optical device E is an optical device E including a light-emitting unit 22 in a first sub-pixel region P1 that emits red light.

For example, the optical device E is an optical device E including a light-emitting unit 22 in a second sub-pixel region P2 that emits green light.

For example, the optical device E is an optical device E including a light-emitting unit 22 in a first sub-pixel region P1 that emits red light and a light-emitting unit 22 in a second sub-pixel region P2 that emits green light.

In this way, it may be conducive to ameliorating the light leakage problem of the optical device E in the display panel 100, and it may also be conducive to ameliorating the color shift problem of the display panel 100 to a certain extent, and is conducive to improving the quality of the display image of the display panel 100 to a certain extent.

In some other examples, each of the buffer layers 21 in some of the optical devices E in the display panel 100 further includes a side surface 213 for connecting the first surface 211 and the second surface 212, the side surface 213 intersects with the first surface 211 to form a first acute angle α, and the side surface 213 intersects with the second surface 212 to form a first obtuse angle θ.

For example, the some of the optical devices E may be optical devices E each including a light-emitting unit 22 in a first sub-pixel region P1 that emits red light.

For example, the some of the optical devices E may be optical devices E each including a light-emitting unit 22 in a second sub-pixel region P2 that emits green light.

For example, the some of the optical devices E may be optical devices E each including a light-emitting unit 22 in a first sub-pixel region P1 that emits red light and a light-emitting unit 22 in a second sub-pixel region P2 that emits green light.

In this way, it may be conducive to ameliorating the light leakage problem of the optical device E including the light-emitting unit 22 in the first sub-pixel region P1 that emits red light and the optical device E including the light-emitting unit 22 in the second sub-pixel region P2 that emits green light in the display panel 100, and is conducive to improving the quality of the display image of the display panel 100 to a certain extent.

In some examples, in each of the optical devices E in the display panel 100, the buffer layer 21 may further include a side surface 213 for connecting the first surface 211 and the second surface 212, the side surface 213 intersects with the first surface 211 to form a first acute angle α, and the side surface 213 intersects with the second surface 212 to form a first obtuse angle θ.

In this way, it may be conducive to ameliorating the light leakage problem of all the optical devices E in the display panel 100, and it may well improve the quality of the display image of the display panel 100.

In summary, in the display panel 100 provided in the embodiments of the present disclosure, the buffer layer 21 may further include a side surface 213 for connecting the first surface 211 and the second surface 212, the side surface 213 intersects with the first surface 211 to form a first acute angle α, and the side surface 213 intersects with the second surface 212 to form a first obtuse angle θ. The side surface 213 of the buffer layer 21 in the optical device E faces the driving backplane 10, so that an inverted triangle structure may be formed at the edge of the buffer layer 21 in the optical device E. It may be conducive to increasing the probability of light being emitted toward the driving backplane 10 through the side surface 213, and in turn reducing the probability of light being emitted toward the optical conversion layer 40, and ameliorating the problem of light leakage at the edge of the optical device E. As a result, the quality of the display image of the display panel 100 is improved.

FIG. 10 is a partial enlarged view of the region Q in FIG. 9.

In some embodiments, referring to FIG. 10, since the light transmitted in the buffer layer 21 will eventually enter the air through the side surface 213, by arranging the side surface 213 intersecting with the first surface 211 to form a first acute angle α and the side surface 213 intersecting with the second surface 212 to form a first obtuse angle θ, it may be possible to increase the probability of light being emitted toward the driving backplane 10 through the side surface 213 to a certain extent, which is conducive to reducing the probability of light being emitted toward the optical conversion layer 40 and ameliorating the problem of light leakage at the edge of the optical device E. As a result, the quality of the display image of the display panel 100 is improved.

The refractive index of the buffer layer 21 is generally greater than the refractive index of the air. When the light enters the air from the side surface 213, the light enters the optically sparse medium from the optically dense medium. When the light transmitted in the buffer layer 21 irradiates the side surface 213, if the incident angle β is greater than

$$arc sin \frac{1}{n 1} ,$$

the light will be totally reflected at the side surface 213 and cannot be emitted from the buffer layer 21. Here, n1 is the refractive index of the buffer layer 21, and the refractive index of the air is generally 1.

Based on this, a value α1 of the first acute angle α formed by the intersection of the side surface 213 and the first surface 211 in the buffer layer 21 may satisfy:

$${0}^{∘} < α1 < {90}^{∘} - arcsin \frac{1}{n 1} .$$

Based on the above structure, among multiple rays of light transmitted in the buffer layer 21, an incident angle of light irradiating the side surface 213 in a direction toward the optical conversion layer 40 may be greater than

$$arcsin \frac{1}{n 1} .$$

Therefore, in the buffer layer 21, the light irradiating the side surface 213 in the direction toward the optical conversion layer 40 may be totally reflected at the position of the side surface 213, which may effectively avoid that the part of light is refracted by the side surface 213 and continues to be directed toward the optical conversion layer 40. The problem of the light leakage at the edge of the optical device E may be effectively ameliorated. As a result, the quality of images displayed on the display panel 100 is improved.

In some embodiments, with continued reference to FIG. 9, the optical conversion layer 40 further includes a plurality of color conversion portions 42. An orthographic projection of a color conversion portion 42 on the driving backplane 10 at least partially overlaps with an orthographic projection of a light-emitting unit 22 on the driving backplane 10.

Since the orthographic projection of the color conversion portion 42 on the driving backplane 10 at least partially overlaps with the orthographic projection of the light-emitting unit 22 on the driving backplane 10, the color conversion part 42 may adjust the light emitted by the light-emitting unit 22 so that each sub-pixel region P0 emits target light to form a displayed image.

In some embodiments, with continued reference to FIG. 9, the color conversion portions 42 further includes first-type conversion portions 421. The first-type color conversion portion 421 is configured to convert a color of light emitted by a light-emitting unit 22 into a target color, so that a sub-pixel region P0 corresponding to the light-emitting unit 22 emits the target light.

In some examples, the first-type color conversion portion 421 is usually a film layer made of an organic material added with a QD material, thus realizing the light conversion effect through the quantum dot material.

In some examples, the first-type color conversion portions 421 include red QD portions 421a and green QD portions 421b. Different QD materials will emit light in different wavelength bands after being excited by an excitation light source. For example, the red QD portion 421a converts the light emitted by the light-emitting unit 22 into red light, and the green QD portion 421b converts the light emitted by the light-emitting unit 22 into green light.

Based on this, the sub-pixel region P0 where the light-emitting unit 22 corresponding to the red QD portion 421a is located may emit red light, and the sub-pixel region P0 where the light-emitting unit 22 corresponding to the green QD portion 421b is located may emit green light, so that the display panel 100 displays an image.

In some embodiments, with continued reference to FIG. 9, the color conversion portions 42 further include second-type color conversion portions 422. The second-type color conversion portion 422 is configured to directly transmit light emitted by a light emitting unit 22. The second-type color conversion portion 422 does not convert the wavelength of the light, and can directly transmit the light emitted by the light-emitting unit 22. Thus, the sub-pixel region P0, where the light-emitting unit 22 corresponding to the second-type color conversion portion 422 is located, can directly emit the color light provided by the light-emitting unit 22.

In some examples, the second-type color conversion portion 422 includes a transparent portion with scattering particles. Due to the scattering particles in the transparent portion, the light emitted by the light-emitting unit 22 may continuously undergo refraction, reflection and scattering inside the second-type color conversion portion 422 when passing through the second-type color conversion portion 422, resulting in a diffusion effect on the light emitted by the light-emitting unit 22.

The light-emitting unit 22 being a blue light-emitting diode chip unit is taken as an example for introduction.

The red QD portion 421a is located in the first sub-pixel region P1, the green QD portion 421b is located in the second sub-pixel region P2, and the second-type color conversion portion 422 is located in the third sub-pixel region P3.

Blue light emitted by the light-emitting unit 22 in the first sub-pixel region P1 can be converted into red light through the red QD portion 421a, so that the first sub-pixel region P1 emits red light. Blue light emitted by the light-emitting unit 22 in the second sub-pixel region P2 can be converted into green light through the green QD portion 421b, so that the second sub-pixel region P2 emits green light. Blue light emitted by the light-emitting unit 22 in the third sub-pixel region P3 can be directly transmitted through the second-type color conversion portion 422, so that the third sub-pixel region P3 emits blue light.

Based on this, by using different color conversion portions 42, the first sub-pixel region P1 in the display panel 100 emits red light, the second sub-pixel region P2 in the display panel 100 emits green light, and the third sub-pixel region P3 in the display panel 100 emits blue light, so as to form a displayed image.

In some embodiments, with continued reference to FIG. 9, the optical conversion layer 40 further includes a blocking portion 41. The blocking portion 41 separates the plurality of color converting portions 42. The blocking portion 41 may be used to avoid a cross-color problem caused by mutual interference between color light emitted by two adjacent color conversion portions 42.

In some embodiments, the blocking portion 41 is made of a light-shielding material. For example, the material of the blocking portion 41 is black resin. However, the embodiments of the present disclosure are not limited thereto.

In some embodiments, with continued reference to FIG. 9, the orthographic projection of the color conversion portion 42 on the driving backplane 10 covers the orthographic projection of the light-emitting unit 22 on the driving backplane 10.

The light emitted by the light-emitting unit 22 will diverge. A size of the color conversion portion 42 is set to be greater than a size of the light-emitting unit 22, so that the orthographic projection of the color conversion portion 42 on the driving backplane 10 covers the orthographic projection of the light-emitting unit 22 on the driving backplane 10. Based on this, the light emitted by the light-emitting unit 22 may enter the color conversion portion 42 as much as possible, so that the color conversion portion 42 adjusts the light and emits the target light. In addition, it may be possible to avoid that the light emitted by the light-emitting unit 22 enters an adjacent color conversion portion 42 to cause problems such as color cast of the display panel 100.

It can be understood that, in some other embodiments, the orthographic projection of the color conversion portion 42 on the driving backplane 10 partially overlaps with the orthographic projection of the light-emitting unit 22 on the driving backplane 10. In yet some other embodiments, the orthographic projection of the color conversion portion 42 on the driving backplane 10 overlaps with the orthographic projection of the light-emitting unit 22 on the driving backplane 10. However, the embodiments of the present disclosure are not limited thereto.

FIG. 11 is a sectional view of yet another display panel, in accordance with some embodiments.

In some embodiments, referring to FIG. 11, the display panel 100 further includes a light-shielding portion 50. The light-shielding portion 50 is located on a side of the first surface 211 of the buffer layer 21 proximate to the driving backplane 10. An orthographic projection of the light-shielding portion 50 on the driving backplane 10 at least partially overlaps with an orthographic projection of the side surface 213 on the driving backplane 10.

In the display panel 100, the light-shielding portion 50 is further provided, and the light-shielding portion 50 is disposed between the first surface 211 of the buffer layer 21 and the driving backplane 10. Thus, the light-shielding portion 50 is located between the side surface 213 of the buffer layer 21 and the driving backplane 10. In addition, the orthographic projection of the light-shielding portion 50 on the driving backplane 10 at least partially overlaps with the orthographic projection of the side surface 213 on the driving backplane 10.

Furthermore, when the light transmitted in the buffer layer 21 is emitted toward the driving backplane 10 through the side surface 213, a large part of the light may be incident on the light-shielding portion 50 and be absorbed by the light-shielding portion 50, which may effectively avoid that this part of the light is reflected by other structures in the display panel 100 to the outside of the display panel 100, which causes the light leakage at the edge of the optical device E. As a result, it may be conducive to improving the quality of the images displayed on the display panel 100.

In some embodiments, with continued reference to FIG. 11, the orthographic projection of the light-shielding portion 50 on the driving backplane 10 covers the orthographic projection of the side surface 213 on the driving backplane 10.

In this way, the orthographic projection of the light-shielding portion 50 on the driving backplane 10 is of a closed structure, so that the light-shielding portion 50 may fully cover the irradiation range of the light emitted toward the driving backplane 10 through the side surface 213. Therefore, the light emitted toward the driving backplane through the side surface 213 may be incident on the light-shielding portion 50 and be absorbed by the light-shielding portion 50, which may effectively avoid that this part of light is reflected by other structures in the display panel 100 to the outside of the display panel 100 to cause the light leakage at the edge of the optical device E. As a result, it may be conducive to improving the quality of the images displayed on the display panel 100.

It can be understood that in some other embodiments, the orthographic projection of the light-shielding portion 50 on the driving backplane 10 partially overlaps with the orthographic projection of the side surface 213 on the driving backplane 10.

The orthographic projection of the side surface 213 on the driving backplane is of a closed structure. Based on this, the description that the orthographic projection of the light-shielding portion 50 on the driving backplane 10 partially overlaps with the orthographic projection of the side surface 213 on the driving backplane 10 may have the following three possible explanations.

The first explanation is that the orthographic projection of the light-shielding portion 50 on the driving backplane 10 is of a non-closed structure, which may be a structure of disconnected multiple segments. Orthographic projections of the multiple segments on the driving backplane 10 are arranged along a peripheral direction of the orthographic projection of the second surface 212 of the buffer layer 21 on the driving backplane 10.

The second explanation is that the orthographic projection of the light-shielding portion 50 on the driving backplane 10 is a closed structure. The orthographic projection of the light-shielding portion 50 on the driving backplane 10 only covers an orthographic projection of a part of the side surface 213 of the buffer layer 21 proximate to the first surface 211 on the driving backplane 10, and the orthographic projection of the light-shielding portion 50 on the driving backplane 10 does not overlap with an orthographic projection of a part of the side surface 213 of the buffer layer 21 proximate to the second surface 212 on the driving backplane 10.

Alternatively, the orthographic projection of the light-shielding portion 50 on the driving backplane 10 is of a closed structure. The orthographic projection of the light-shielding portion 50 on the driving backplane 10 only covers the orthographic projection of the part of the side surface 213 of the buffer layer 21 proximate to the second surface 212 on the driving backplane 10, and the orthographic projection of the light-shielding portion 50 on the driving backplane 10 does not overlap with the orthographic projection of the part of the side surface 213 of the buffer layer 21 proximate to the first surface 211 on the driving backplane 10.

The third explanation includes the situations mentioned in the above first and second explanations. That is, the orthographic projection of the light-shielding portion 50 on the driving backplane 10 is a non-closed structure. In addition, the orthographic projection of the light-shielding portion 50 on the driving backplane 10 only covers the orthographic projection of the part of the side surface 213 of the buffer layer 21 proximate to the first surface 211 on the driving backplane 10, and the orthographic projection of the light-shielding portion 50 on the driving backplane 10 does not overlap with the orthographic projection of the part of the side surface 213 of the buffer layer 21 proximate to the second surface 212 on the driving backplane 10.

Alternatively, the orthographic projection of the light-shielding portion 50 on the driving backplane 10 is of a non-closed structure. The orthographic projection of the light-shielding portion 50 on the driving backplane 10 only covers the orthographic projection of the part of the side surface 213 of the buffer layer 21 proximate to the second surface 212 on the driving backplane 10, and the orthographic projection of the light-shielding portion 50 on the driving backplane 10 does not overlap with the orthographic projection of the part of the side surface 213 of the buffer layer 21 proximate to the first surface 211 on the driving backplane 10.

The following description is introduced by taking an example in which the orthographic projection of the light-shielding portion 50 on the driving backplane 10 is a closed structure.

In some examples, referring to FIG. 11, the light-shielding portion 50 includes a first light-shielding portion 51. The first light-shielding portion 51 is located on the side surface 213, and the first light-shielding portion 51 is in contact with the side surface 213. An orthographic projection of the first light-shielding portion 51 on the driving backplane 10 at least partially overlaps with the orthographic projection of the side surface 213 on the driving backplane 10.

In some examples, the orthographic projection of the first light-shielding portion 51 on the driving backplane 10 partially overlaps with the orthographic projection of the side surface 213 on the driving backplane 10. As for the partial overlap, reference may be made to the above description of the partial overlap. The first light-shielding portion 51 is disposed on a part of side surface 213, and the first light-shielding portion 51 may be used to absorb light emitted from the buffer layer 21 through the part of the side surface 213, thereby ameliorating the light leakage at the edge of the optical device E to a certain extent.

In some examples, the orthographic projection of the first light-emitting portion 51 on the driving backplane 10 overlaps with the orthographic projection of the side surface 213 on the driving backplane 10. FIG. 11 illustrates an example in which the orthographic projection of the first light-shielding portion 51 on the driving backplane overlaps with the orthographic projection of the side surface 213 on the driving backplane 10.

On the basis that the first light-shielding portion 51 is located on the side 213 and the first light-shielding portion 51 is in contact with the side surface 213, the orthographic projection of the first light-shielding portion 51 on the driving backplane overlaps with the orthographic projection of the side surface 213 on the driving backplane 10, so that the side surface 213 may be blocked by the first light-shielding portion 51, Therefore, it may be possible to ensure that the first light-shielding portion 51 can absorb the light emitted from the buffer layer 21 through the side surface 213, and in turn effectively ameliorate the light leakage at the edge of the optical device E and improve the quality of the images displayed on the display panel 100.

In some examples, the orthographic projection of the first light-emitting portion 51 on the driving backplane 10 covers the orthographic projection of the side surface 213 on the driving backplane 10.

The first light-shielding portion 51 is directly disposed on the side surface 213 and is completely cover the side surface 213. When the light transmitted in the buffer layer 21 is emitted from the side surface 213, the light may all be incident on the first light-shielding portion 51, and then the light may be blocked and absorbed by the first light-shielding portion 51. Therefore, it may be possible to effectively avoid that the light transmitted in the buffer layer 21 is refracted by the side surface 213 and then directed toward the optical conversion layer 40 and exits the display panel 100, and in turn effectively ameliorate the light leakage at the edge of the optical device E and improve the quality of the images displayed on the display panel 100.

In some embodiments, the first light-shielding portion 51 is made of a light absorption material. For example, the material of the first light-shielding portion 51 adopts at least one of molybdenum, chromium, aluminum, titanium and copper with low reflectivity, or an alloy containing at least one of the above metals, or metal oxide and metal nitride corresponding to any of the above metals. However, the embodiments of the present disclosure are not limited thereto.

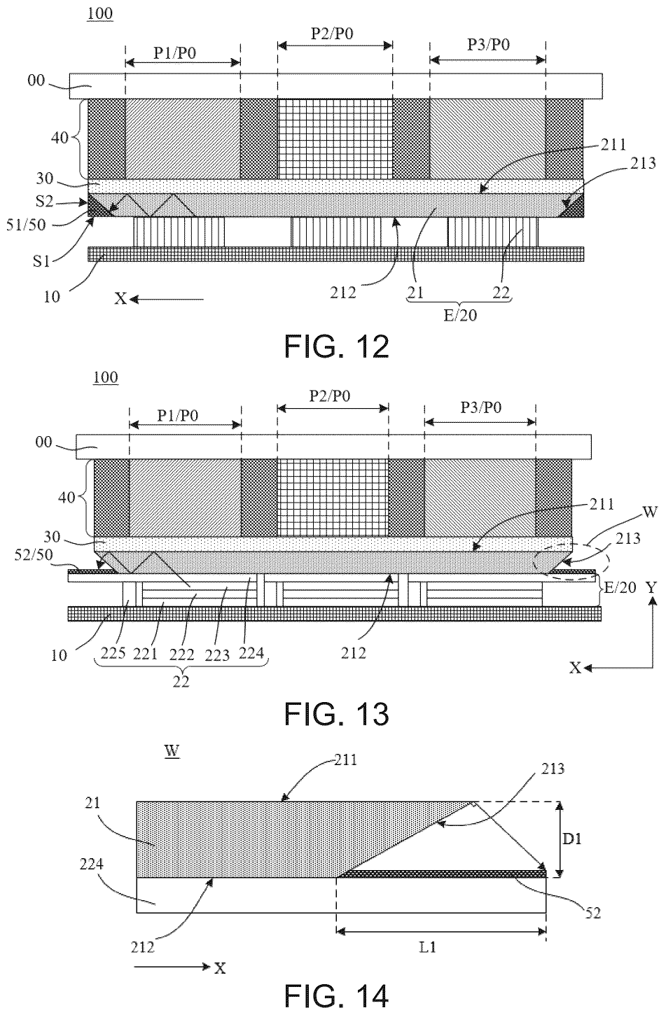

FIG. 12 is a sectional view of yet another display panel, in accordance with some embodiments.

In some embodiments, as shown in FIG. 12, a surface S1, close to the driving backplane 10, of the first light-shielding portion 51 is flush with the second surface 212.

In this way, the surface S1, proximate to the driving backplane 10, of the first light-shielding portion 51 and the second surface 212 may be located in the same plane, which may be conducive to improving the flatness of the display panel 100. In addition, it may also be conducive to increasing a thickness of a part of the first light-shielding portion 51, and may also be conducive to improving the light-absorbing effect of the first light-shielding portion 51. Therefore, it may avoid that the light in the buffer layer 21 is refracted by the side surface 213 and then directed toward the optical conversion layer 40 to exit from the display panel 100. As a result, it may be possible to effectively ameliorate the light leakage at the edge of the optical device E and improve the quality of the display images of the display panel 100.

In some embodiments, as shown in FIG. 12, an orthographic projection of a surface, away from the buffer layer 21 in a first direction X, of the first light-shielding portion 51 on the driving backplane 10 overlaps with a boundary of the orthographic projection of the first surface 211 on the driving backplane 10. The first direction X is parallel to the driving backplane 10.

In this way, the surface S2 of the first light-shielding portion 51 away from the buffer layer 21 in the first direction X and an edge of the second surface 211 are located in the same plane, which may be conducive to improving the flatness of the display panel 100. In addition, it may also be conducive to increasing a thickness of a part of the first light-shielding portion 51, and may also be conducive to improving the light-absorbing effect of the first light-shielding portion 51. Therefore, it may avoid that the light in the buffer layer 21 is refracted by the side surface 213 and then directed toward the optical conversion layer 40 to exit from the display panel 100. As a result, it may be possible to effectively ameliorate the light leakage at the edge of the optical device E and improve the quality of the display images of the display panel 100.

In some embodiments, as shown in FIG. 12, the surface S1 of the first light-shielding portion 51 proximate to the driving backplane 10 is flush with the second surface 212, and the orthographic projection of the surface, away from the buffer layer 21 in the first direction X, of the first light-shielding portion 51 on the driving backplane overlaps with the boundary of the orthographic projection of the first surface 211 on the driving backplane 10. The first direction X is parallel to the driving backplane 10. Therefore, the orthographic projection of first light-shielding portion 51 on the driving backplane 10 overlaps with the orthographic projection of the side surface 213 on the driving backplane 10.

In this way, it is conductive to improving the flatness of the display panel 100. In addition, it may also be conducive to increasing a thickness of a part of the first light-shielding portion 51, and may also be conducive to improving the light-absorbing effect of the first light-shielding portion 51. Therefore, it may avoid that the light in the buffer layer 21 is refracted by the side surface 213 and then directed toward the optical conversion layer 40 to exit from the display panel 100. As a result, it may be possible to effectively ameliorate the light leakage at the edge of the optical device E and improve the quality of the display images of the display panel 100.

In addition, since the first light-shielding portion 51 is directly formed on the side surface 213 of the buffer layer 21, the surface S1 of the first light-shielding portion 51 proximate to the driving backplane 10 is flush with the second surface 212, and the orthographic projection of the surface, away from the buffer layer 21 in the first direction X, of the first light-shielding portion 51 on the driving backplane 10 overlaps with the boundary of the orthographic projection of the first surface 211 on the driving backplane 10. Therefore, the orthographic projection of first light-shielding portion 51 on the driving backplane 10 overlaps with the orthographic projection of the side surface 213 on the driving backplane 10. On this basis, the first light-shielding portion 51 may absorb all the light emitted through the side surface 213, and there is no need to expand the size of the first light-shielding portion 51, which can help save resources.

FIG. 13 is a sectional view of yet another display panel, in accordance with some embodiments.

In some embodiments, referring to FIG. 13, in a direction Y away from the driving backplane 10, the light-emitting unit 22 includes: a first electrode 221, a first semiconductor layer 222 electrically connected to the first electrode 221, a light-generating layer 223, and a second semiconductor layer 224. The light-emitting unit 22 further includes a second electrode 225 electrically connected to the second semiconductor layer 224. The second electrode 225 is located on a side of the second semiconductor layer 224 proximate to the driving backplane 10.

In the case where different voltages are respectively applied to the first electrode 221 and the second electrode 225 to create an electric field therebetween, a PN junction with a potential barrier is created between the first semiconductor layer 222 and the second semiconductor layer 224, and carriers in the first semiconductor layer 222 and carriers in the second semiconductor layer 224 enter the light-generating layer 223 and recombine. At this time, excess energy is released in a form of light, and thus electric energy is directly converted into light energy to enable the light emission of the light-emitting unit 22.

In some examples, the first semiconductor layer 222 is one of an N-type semiconductor and a P-type semiconductor, and the second semiconductor layer 224 may be another of an N-type semiconductor and a P-type semiconductor.

In some examples, the first semiconductor layer 222 and the second semiconductor layer 224 are made of gallium nitride (GaN).

Considering an example in which the first semiconductor layer 222 is a P-type semiconductor and the second semiconductor layer 224 is an N-type semiconductor, the first semiconductor layer 222 may be made of N—GaN, and the second semiconductor layer 224 may be made of P—GaN.

In some examples, the first electrode 221 electrically connected to the first semiconductor layer 222 is an anode of the light-emitting unit 22. The first electrode 221 may be made of chromium platinum alloy or tin silver alloy. However, the embodiments of the present disclosure are not limited thereto.

In some examples, the second electrode 225 electrically connected to the second semiconductor layer 224 is a cathode of the light-emitting unit 22. The second electrode 225 may be made of chromium platinum alloy or tin silver alloy. However, the embodiments of the present disclosure are not limited thereto.

In some examples, the light-generating layer 223 is a multiple quantum well (MQW) layer.

It should be noted that the structure of the light-emitting unit 22 in any of the embodiments herein can be the same as the structure of the light-emitting unit 22 shown in FIG. 13; and as for the structure of the light-emitting unit in other embodiments, reference can be made to the structure of the light-emitting unit 22 shown in FIG. 13.

In some embodiments, with continued reference to FIG. 13, the light-shielding portion 50 further includes a second light-shielding portion 52, and the second light-shielding portion 52 is located on a side of the second semiconductor layer 224 away from the second electrode 225. An orthographic projection of the second light-shielding portion 52 on the driving backplane 10 at least partially overlaps with the orthographic projection of the side surface 213 of the buffer layer 21 on the driving backplane 10.

In some examples, the orthographic projection of the second light-shielding portion 52 on the driving backplane 10 partially overlaps with the orthographic projection of the side surface 213 of the buffer layer 21 on the driving backplane 10. As for the partial overlap, reference may be made to the above description of the partial overlap. Since the orthographic projection of the second light-shielding portion 52 on the driving backplane 10 partially overlaps with the orthographic projection of the side surface 213 of the buffer layer 21 on the driving backplane 10, the second light-shielding portion 52 can be used to absorb a large part of light emitted from the buffer layer 21 through part of the side surface 213. As a result, the light leakage at the edge of the optical device E is ameliorated to a certain extent.

In some other examples, the orthographic projection of the second light-shielding portion 52 on the driving backplane 10 overlaps with the orthographic projection of the side surface 213 of the buffer layer 21 on the driving backplane 10.

The second light-shielding portion 52 is located between the side surface 213 and the driving backplane 10, and a size of the orthographic projection of the second light-shielding portion 52 on the driving backplane 10 is approximately the same as a size of the orthographic projection of the side surface 213 of the buffer layer 21 on the driving backplane 10. A large part of the light that is transmitted in the buffer layer 21 and directed toward the driving backplane 10 after being refracted by the side surface 213 may be incident on the second light-shielding portion 52 and be absorbed by the second light-shielding portion 52. Therefore, it may be possible to effectively avoid that the part of light is reflected by other structures in the display panel 100 to the outside of the display panel 100, causing the light leakage at the edge of the optical device E. As a result, it may be conducive to improving the quality of the images displayed on the display panel 100.

In yet some other examples, the orthographic projection of the second light-shielding portion 52 on the driving backplane 10 covers the orthographic projection of the side surface 213 of the buffer layer 21 on the driving backplane 10.

The second light-shielding portion 52 is located between the side surface 213 and the driving backplane 10, and the size of the orthographic projection of the second light-shielding portion 52 on the driving backplane 10 is slightly greater than the size of the orthographic projection of the side surface 213 of the buffer layer 21 on the driving backplane 10. A portion of the second light-shielding portion 52, whose orthographic projection on the driving backplane 10 expanding outward relative to the orthographic projection of the side surface 213 of the buffer layer 21 on the driving backplane 10, is used to absorb light that is directed toward the driving backplane 10 and diverges toward the edge of the side surface 213 after being refracted by the side surface 213. Based on this, the second light-shielding portion 52 is used to absorb all the light directed toward the driving backplane 10 after being refracted by the side surface 213, which may effectively avoid that the light is reflected by other structures in the display panel 100 to the outside of the display panel 100, causing the light leakage at the edge of the optical device E. As a result, it may be conducive to improving the quality of the images displayed on the display panel 100.

In some examples, the second light-shielding portion 52 is made of a light-absorbing material. For example, the material of the second light-shielding portion 52 adopts at least one of molybdenum, chromium, aluminum, titanium and copper with low reflectivity, or an alloy containing at least one of the above metals, or metal oxide and metal nitride corresponding to any of the above metals. However, the embodiments of the present disclosure are not limited thereto.

In some embodiments, the first light-shielding portion 51 and the second light-shielding portion 52 may be provided in the display panel 100 at the same time. The embodiments of the present disclosure are not limited thereto.

In some embodiments, with continued reference to FIG. 13, a part of the second light-shielding portion 52 proximate to the buffer layer 21 is in contact with a part of the side surface 213 of the buffer layer 21 proximate to the second surface 212.

It means that the second light-shielding portions 52 is arranged around and adjacent to the part of the side surface 213 of the buffer layer 21 proximate to the second surface 212. The second light-shielding portion 52 may absorb all the light emitted through the part of the side surface 213 proximate to the second surface 212. That is, the second light-shielding portion 52 may absorb all light emitted through one end of the side surface 213. It may be possible to effectively avoid that the light is reflected by other structures in the display panel 100 to the outside of the display panel 100, causing the light leakage at the edge of the optical device E. As a result, it may be conducive to improving the quality of the images displayed on the display panel 100.

In some other embodiments, with continued reference to FIG. 13, a boundary of the orthographic projection of the second light-shielding portion 52 on the driving backplane 10 exceeds a boundary of the orthographic projection of the first surface 211 on the driving backplane 10.

It means that the second light-shielding portion 52 is arranged around the part of the side surface 213 of the buffer layer 21 proximate to the second surface 212, and a part of the second light-shielding portion 52 away from the buffer layer 21 expands outward slightly, so as to enable the orthographic projection of the second light-shielding portion 52 on the driving backplane 10 covering the boundary of the orthographic projection of the first surface 211 on the driving backplane 10. Based on this, the second light-shielding portion 52 may absorb all light emitted through the part of the side surface 213 proximate to the first surface 211 of the buffer layer 21. That is, the second light-shielding portion 52 may absorb all light emitted through another end of the side surface 213. It may be possible to effectively avoid that the light is reflected by other structures in the display panel 100 to the outside of the display panel 100, causing the light leakage at the edge of the optical device E. As a result, it may be conducive to improving the quality of the images displayed on the display panel 100.

In yet some other embodiments, with continued reference to FIG. 13, the part of the second light-shielding portion 52 proximate to the second surface 212 is in contact with the part of the side surface 213 of the buffer layer 21 proximate to the second surface 212, and the boundary of the orthographic projection of the second light-shielding portion 52 on the driving backplane 10 exceeds the boundary of the orthographic projection of the first surface 211 on the driving backplane 10.

In this way, it means that the second light-shielding portions 52 is arranged around and adjacent to the part of the side surface 213 of the buffer layer 21 proximate to the second surface 212, and the part of the second light-shielding portion 52 away from the buffer layer 21 expands outward slightly. Based on this, the second light-shielding portion 52 covers the irradiation region of the light that is transmitted in the buffer layer 21 and directed toward the driving backplane 10 through the side surface 213. Furthermore, the light transmitted in the buffer layer 21 and directed toward the driving backplane 10 through the side surface 213 may be incident on the second light-shielding portion 52 and absorbed by the second light-shielding portion 52, which may effectively avoid that the light is reflected by other structures in the display panel 100 to the outside of the display panel 100, causing the light leakage at the edge of the optical device E. As a result, it may be conducive to improving the quality of the images displayed on the display panel 100.

FIG. 14 is a partial enlarged view of the region W in FIG. 13.

In some embodiments, referring to FIG. 14, the part of the second light-shielding portion 52 proximate to the second surface 212 is in contact with the part of the side surface 213 of the buffer layer 21 proximate to the second surface 212, and the boundary of the orthographic projection of the second light-shielding portion 52 on the driving backplane 10 exceeds the boundary of the orthographic projection of the first surface 211 on the driving backplane 10.

In this case, a width L1 of the second light-shielding portion 52 in the first direction X satisfies:

$$L 1 > \frac{D 1}{sin α1 \times cos α1} .$$

Here, α1 is the value of the first acute angle α, D1 is a thickness of the buffer layer 21, and the first direction X is parallel to the driving backplane 10.

In the case where light transmitted in the buffer layer 21 is vertically directed to a side proximate to the second semiconductor layer 224 through the side surface 213, the light may be incident on the second light-shielding portion 52. That is, in the case where the light transmitted in the buffer layer 21 is directed toward the second semiconductor layer 224 through the side surface 213, the light may be incident on the second light-shielding portion 52.

Based on this, in the case where the width L1 of the second light-shielding portion 52 in the first direction X is equal to or approaches

$$\frac{D 1}{sin α1 \times cos α1} ,$$

when the light transmitted in the buffer layer 21 is directed toward the second semiconductor layer 224 through the side surface 213, the light may be incident on the second light-shielding portion 52; in addition, it may be possible to avoid that the length of the second light-shielding portion 52 is too long, which affects the aperture ratio in the display panel 100.

It should be noted that since the thickness of the second light-shielding portion 52 is small, it can be negligible. The formula that the width L1 of the second light-shielding portion 52 satisfies is determined in the case where the thickness of the second light-shielding portion 52 is negligible.

In some examples, with continued reference to FIG. 14, the width L1 of the second light-shielding portion 52 in the first direction X is approximately

$$\frac{D 1}{sin α1 \times cos α1} .$$

In the case where the width L1 of the second light-shielding portion 52 in the first direction X is approximately

$$\frac{D 1}{sin α1 \times cos α1} ,$$

the influence of the second light-shielding portion 52 on the aperture ratio in the display panel 100 may be reduced to a greatest extent; in addition, it may be possible to realize that when the light transmitted in the buffer layer 21 is directed toward the second semiconductor layer 224 through the side surface 213, the light may be incident on the second light-shielding portion 52 and be absorbed by the second light-shielding portion 52. Therefore, the light leakage at the edge of the optical device E may be effectively ameliorated, and the quality of the images displayed on the display panel 100 is improved.

It should be noted that due to certain uncontrollable deviations (such as manufacturing process deviation, equipment accuracy, etc.), when a floating range of a deviation of the width L1 of the second light-shielding portion 52 is within

$$5 \% \times \frac{D 1}{sin α1 \times cos α1} ,$$

it can be considered that the width L1 of the second light-shielding portion 52 is equal to or approximately equal to

$$\frac{D 1}{sin α1 \times cos α1} .$$

Other numerical floating ranges of the width L1 of the second light-shielding portion 52 are as above, which will not be repeated here.

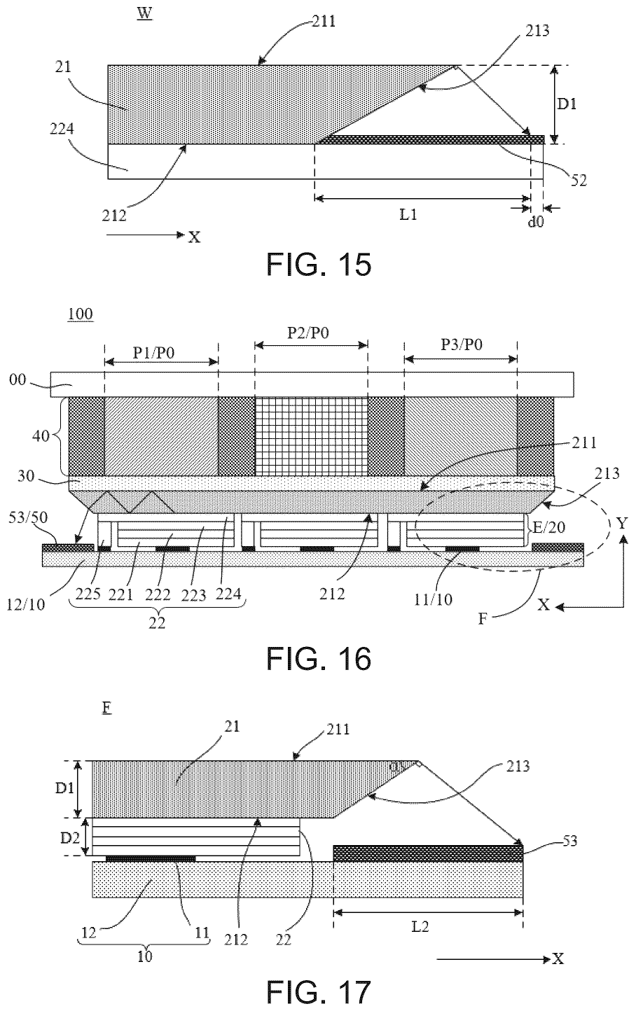

FIG. 15 is another partial enlarged view of the region W in FIG. 13.

In some embodiments, referring to FIG. 15, the part of the second light-shielding portion 52 proximate to the second surface 212 is in contact with the part of the side 213 of the buffer layer 21 proximate to the second surface 212, and the boundary of the orthographic projection of the second light-shielding portion 52 on the driving backplane 10 exceeds the boundary of the orthographic projection of the first surface 211 on the driving backplane 10; in this case, the part of the second light-shielding portion 52 away from the buffer layer 21 expands outward by a distance d0, so that the second light-shielding portion 52 may fully cover the irradiation range of the light emitted toward the driving backplane 10 through the side surface 213. Therefore, the light emitted toward the driving backplane 10 through the side surface 213 may all be incident on the light-shielding portion 50 and be absorbed by the light-shielding portion 50, and the light leakage at the edge of the optical device E is ameliorated.

That is, in the first direction X,

$$L 1 > \frac{D 1}{sin α1 \times cos α1} + d 0$$

is satisfied. Here, α1 is the value of the first acute angle α, D1 is the thickness of the buffer layer 21, d0 is the distance by which the part of the second light-shielding portion 52 expands outward in the first direction X, and the first direction X is parallel to the driving backplane 10.

When the width L1 of the second light-shielding portion 52 is equal to or approaches

$$\frac{D 1}{sin α1 \times cos α1} + d 0 ,$$

the second light-shielding portion 52 may be expanded toward a side thereof away from the buffer layer 21 in the first direction X, so that the second light-shielding portion 52 fully covers the irradiation range of the light emitted toward the driving backplane 10 through the side surface 213. Therefore, all the light emitted toward the driving backplane 10 through the side surface 213 may be incident on the light-shielding portion 50 and be absorbed by the light-shielding portion 50, which ameliorates the light leakage at the edge of the optical device E.

The embodiments of the present disclosure do not specifically limit the magnitude of the distance d0 by which the part of the second light-shielding portion 52 away from the buffer layer 21 expands outward in the first direction X.

In some embodiments, referring to FIG. 15, the width L1 of the second light-shielding portion 52 in the first direction X satisfies:

$$L 1 = \frac{D 1}{sin α1 \times cos α1} + d 0.$$

In the case where the width L1 of the second light-shielding portion 52 in the first direction X is approximately

$$\frac{D 1}{sin α1 \times cos α1} + d 0 ,$$

when the light transmitted in the buffer layer 21 is emitted to the driving backplane 10 through the side surface 213, the light may be incident on the second light-shielding portion 52 and be absorbed by the second light-shielding portion 52, so that the influence of the second light-shielding portion 52 on the aperture ratio in the display panel 100 may be reduced to a greatest extent.

It should be noted that due to certain uncontrollable deviations (such as manufacturing process deviation, equipment accuracy, etc.), when a floating range of a deviation of the width L1 of the second light-shielding portion 52 is within

$$5 \% \times ( \frac{D 1}{sin α1 \times cos α1} + d 0 ) ,$$

it can be considered that the width L1 of the second light-shielding portion 52 is equal to or approximately equal to

$$\frac{D 1}{sin α1 \times cos α1} + d 0.$$

Other numerical floating ranges of the width L1 of the second light-shielding portion 52 are as above, which will not be repeated here.

FIG. 16 is a sectional view of yet another display panel, in accordance with some embodiments.

In some embodiments, referring to FIG. 16, the driving backplane 10 includes a base substrate 12 and a plurality of connection electrodes 11 disposed on the base substrate 12. The driving backplane 10 is electrically connected to the light-emitting units 22 through the connection electrodes 11.

For example, a connection electrode of the plurality of connection electrodes 11 is electrically connected to the first electrode 221 in the light-emitting unit 22, and another connection electrode of the plurality of connection electrodes 11 is electrically connected to the second electrode 225 in the light-emitting unit 22, so that the light-emitting unit 22 is electrically connected to the driving backplane 10. Thus, the driving backplane 10 drives the light-emitting unit 22 to emit light.

In some examples, the base substrate 12 may be a flexible base. For example, the base substrate 12 is made of an organic material. For example, the base substrate 12 is made of anyone of polyimide (PI), polycarbonate (PC) or polyvinyl chloride (PVC).

In some other examples, the base substrate 12 is a rigid base. For example, the rigid base is a glass base or a polymethyl methacrylate (PMMA) base.

In some embodiments, the driving backplane 10 further includes a driving circuit layer. The driving circuit layer may be located between the base substrate 12 and the connection electrodes 11. The driving circuit layer is used to control the connection electrodes 11 to transmit electrical signals to first electrodes 221 and second electrodes 225 in the light-emitting units 22, so as to drive the light-emitting units 22 to emit light.

In some embodiments, with continued reference to FIG. 16, the light-shielding portion 50 further includes a third light-shielding portion 53, and the third light-shielding portion 53 is located on a side of the base substrate 12 proximate to the buffer layer 21. An orthographic projection of the third light-shielding portion 53 on the base substrate 12 at least partially overlaps with an orthographic projection of the side surface 213 on the base substrate 12.

In some examples, the orthographic projection of the third light-shielding portion 53 on the base substrate 12 partially overlaps with the orthographic projection of the side surface 213 on the base substrate 12. As for the partial overlap, reference may be made to the above description of the partial overlap.

The third light-shielding portion 53 is located between the buffer layer 21 and the base substrate 12, and the orthographic projection of the third light-shielding portion 53 on the base substrate 12 overlaps with the orthographic projection of the side surface 213 on the base substrate 12. The third light-shielding portion 53 may absorb a large part of the light emitted from the buffer layer 21 toward the base substrate 12 through a part of the side surface 213, so as to ameliorate the light leakage at the edge of the optical device E to a certain extent.

In some other examples, the orthographic projection of the third light-shielding portion 53 on the base substrate 12 overlaps with the orthographic projection of the side surface 213 on the base substrate 12.

The third light-shielding portion 53 is disposed between the buffer layer 21 and the base substrate 12, and a size of an orthographic projection of the third light-shielding portion 53 on the driving backplane 10 is approximately the same as the size of the orthographic projection of the side surface 213 of the buffer layer 21 on the driving backplane 10. A large part of light that is transmitted in the buffer layer 21 and emitted toward the base substrate 12 after being refracted by the side surface 213 is incident on the third light-shielding portion 53 and is absorbed by the third light-shielding portion 53. Therefore, it may be possible to effectively avoid that the part of light is reflected by other structures in the display panel 100 to the outside of the display panel 100, causing the light leakage at the edge of the optical device E. As a result, it may be conducive to improving the quality of the images displayed on the display panel 100.

In some other examples, the orthographic projection of the third light-shielding portion 53 on the base substrate 12 covers the orthographic projection of the side surface 213 on the base substrate 12.

The third light-shielding portion 53 is disposed between the buffer layer 21 and the base substrate 12, and the size of the orthographic projection of the third light-shielding portion 53 on the driving backplane 10 is slightly greater than the size of the orthographic projection of the side surface 213 of the buffer layer 21 on the driving backplane 10. That is, the orthographic projection of the third light-shielding portion 53 on the driving backplane 10 expands outward relative to the orthographic projection of the side surface 213 of the buffer layer 21 on the driving backplane 10. A portion of the third light-shielding portion 53, whose orthographic projection of on the driving backplane 10 expands outward, is used to absorb light that is directed toward the driving backplane 10 and diverges toward the edge of the side surface 213 after being refracted by the side surface 213. Based on this, the third light-shielding portion 53 is used to absorb all the light directed toward the driving backplane 10 after being refracted by the side surface 213, which may effectively avoid that the light is reflected by other structures in the display panel 100 to the outside of the display panel 100, causing the light leakage at the edge of the optical device E. As a result, it may be conducive to improving the quality of the images displayed on the display panel 100.

In some examples, the third light-shielding portion 53 is made of a light-absorbing material. For example, the material of the third light-shielding portion 53 adopts at least one of molybdenum, chromium, aluminum, titanium and copper with low reflectivity, or an alloy containing at least one of the above metals, or metal oxide and metal nitride corresponding to any of the above metals. However, the embodiments of the present disclosure are not limited thereto.

In some embodiments, the display panel 100 may include both the first light-shielding portion 51 and the third light-shielding portion 53. In some other embodiments, the display panel 100 may include both the second light-shielding portion 52 and the third light-shielding portion 53. In yet some other embodiments, the display panel 100 may include the first light-shielding portion 51, the second light-shielding portion 52 and the third light-shielding portion 53. The embodiments of the present disclosure are not limited thereto.

In some embodiments, with continued reference to FIG. 16, an orthographic projection, on the base substrate 12, of a part of the third light-shielding portion 53 proximate to the light-emitting unit 22 is in contact with the boundary of the orthographic projection, on the base substrate 12, of the second surface 212.

The orthographic projection of the part of the third light-shielding portion 53 proximate to the light-emitting unit 22 on the base substrate 12 is in contact with the boundary of the orthographic projection of the second surface 212 of the buffer layer 21 on the base substrate 12.

It means that the orthographic projection of the third light-shielding portion 53 on the base substrate 12 is arranged around and adjacent to the boundary the orthographic projection of the second surface 212 of the buffer layer 21 on the base substrate 12. The third light-shielding portion 53 may absorb a large part of light emitted through the part of the side surface 213 proximate to the second surface 212.

That is, the third light-shielding portion 53 may absorb all light emitted through one end of the side surface 213. It may be possible to effectively avoid that the light is reflected by other structures in the display panel 100 to the outside of the display panel 100, causing the light leakage at the edge of the optical device E. As a result, it may be conducive to improving the quality of the images displayed on the display panel 100.

In some other embodiments, with continued reference to FIG. 16, a boundary of the orthographic projection of the third light-shielding portion 53 on the base substrate 12 exceeds the boundary of the orthographic projection of the first surface 211 on the base substrate 12.

It means that the orthographic projection of the third light-shielding portion 53 on the base substrate 12 is arranged around the boundary of the orthographic projection of the first surface 211 of the buffer layer 21 on the base substrate 12, and a part of the third light-shielding portion 53 away from the buffer layer 21 expands outward slightly, so as to enable the orthographic projection of the third light-shielding portion 53 on the driving backplane 10 covering the boundary of the orthographic projection of the first surface 211 on the driving backplane 10. Based on this, the third light-shielding portion 53 may absorb all light emitted through the part of the side surface 213 proximate to the first surface 211 of the buffer layer 21. That is, the third light-shielding portion 53 may absorb all light emitted through another end of the side surface 213. It may be possible to effectively avoid that the light is reflected by other structures in the display panel 100 to the outside of the display panel 100, causing the light leakage at the edge of the optical device E. As a result, it may be conducive to improving the quality of the images displayed on the display panel 100.

In yet some other embodiments, with continued reference to FIG. 16, the orthographic projection of the part of the third light-shielding portion 53 proximate to the light-emitting unit 22 on the base substrate 12 is in contact with the boundary of the orthographic projection of the second surface 212 on the base substrate 12; and the boundary of the orthographic projection of the third light-shielding portion 53 on the base substrate 12 exceeds the boundary of the orthographic projection of the first surface 211 on the base substrate 12.

It means that the orthographic projection of the third light-shielding portion 53 on the base substrate 12 is arranged around and adjacent to the boundary the orthographic projection of the second surface 212 of the buffer layer 21 on the base substrate 12, and a part of the third light-shielding portion 53 away from the buffer layer 21 expands outward slightly. Based on this, the third light-shielding portion 53 covers the irradiation region of the light that is transmitted in the buffer layer 21 and directed toward the driving backplane 10 through the side surface 213. Furthermore, the light transmitted in the buffer layer 21 and directed toward the driving backplane through the side surface 213 may be incident on the third light-shielding portion 53 and absorbed by the third light-shielding portion 53, which may effectively avoid that the light is reflected by other structures in the display panel 100 to the outside of the display panel 100, causing the light leakage at the edge of the optical device E. As a result, it may be conducive to improving the quality of the images displayed on the display panel 100.

FIG. 17 is a partial enlarged view of the region F in FIG. 16.

In some embodiments, referring to FIG. 17, the orthographic projection of the part of the third light-shielding portion 53 proximate to the light-emitting unit 22 on the base substrate 12 is in contact with the boundary of the orthographic projection of the second surface 212 on the base substrate 12; and the boundary of the orthographic projection of the third light-shielding portion 53 on the base substrate 12 exceeds the boundary of the orthographic projection of the first surface 211 on the base substrate 12.

In this case, a width L2 of the third light-shielding portion 53 in the first direction X satisfies:

$$L 2 > \frac{D 1 + D 2}{sin α1 \times cos α1} - \frac{D 2 \times cos α1}{sin α1} .$$

Here, α1 is the value of the first acute angle α, D1 is the thickness of the buffer layer 21, D2 is a thickness of the light-emitting unit 22, and the first direction X is parallel to the driving backplane 10.

In the case where light transmitted in the buffer layer 21 is vertically directed to a side proximate to the base substrate 12 through the side surface 213, the light may be incident on the third light-shielding portion 53. That is, in the case where the light transmitted in the buffer layer 21 is directed toward the second semiconductor layer 224 through the side surface 213, the light may be incident on the third light-shielding portion 53.

Based on this, in the case where the width L2 of the third light-shielding portion 53 is equal to or approaches

$$\\ \frac{D 1 + D 2}{sin α 1 \times cos α 1} - \frac{D 2 \times cos α 1}{sin α 1} ,$$

when the light transmitted in the buffer layer 21 is directed toward the base substrate 12 through the side surface 213, the light may be incident on the third light-shielding portion 53; in addition, it may be possible to avoid that the length of the third light-shielding portion 53 is too long, which affects the aperture ratio in the display panel 100.

It should be noted that since the thickness of the third light-shielding portion 53 is small, it can be negligible. The formula that the width L2 of the third light-shielding portion 53 satisfies is determined in the case where the thickness of the third light-shielding portion 53 is negligible.

In some examples, with continued reference to FIG. 17, in order to clearly illustrate the structure of the light-emitting unit 22 in FIG. 17, the thickness of each film layer in the light-emitting unit 22 is enlarged, and the thickness of the light-emitting unit 22 is not actual. It can be understood that, in practice, the thickness of the light-emitting unit 22 is generally smaller than the thickness of the buffer layer 21 and may even be negligible. In this case, the width L2 of the third light-shielding portion 53 in the first direction X may satisfy:

$$\\ L 2 > \frac{D 1}{sin α 1 \times cos α 1} .$$

When the width L2 of the third light-shielding portion 53 satisfies the above formula, the light transmitted in the buffer layer 21 is directed toward the base substrate 12 through the side surface 213, and then the light may be incident on the third light-shielding portion 53 and absorbed by the third light-shielding portion 53. Therefore, it may effectively avoid that this part of light is reflected by other structures in the display panel 100 to the outside of the display panel 100, which causes the light leakage at the edge of the optical device E. As a result, it may be conducive to improving the quality of the images displayed on the display panel 100.

In some examples, referring to FIG. 17, the orthographic projection of the part of the third light-shielding portion 53 proximate to the light-emitting unit 22 on the base substrate 12 is in contact with the boundary of the orthographic projection of the second surface 212 on the base substrate 12; and the boundary of the orthographic projection of the third light-shielding portion 53 on the base substrate 12 exceeds the boundary of the orthographic projection of the first surface 211 on the base substrate 12.

In this case, the width L2 of the third light-shielding portion 53 in the first direction X is approximately

$$\\ \frac{D 1 + D 2}{sin α 1 \times cos α 1} - \frac{D 2 \times cos α 1}{sin α 1} .$$

In the case where the width L2 of the third light-shielding portion 53 in the first direction X is approximately

$$\\ \frac{D 1 + D 2}{sin α 1 \times cos α 1} - \frac{D 2 \times cos α 1}{sin α 1} ,$$

the influence of the third light-shielding portion 53 on the aperture ratio in the display panel 100 may be reduced to a greatest extent. In addition, when the light transmitted in the buffer layer 21 is emitted to the base substrate 12 through the side surface 213, the light may be incident on the third light-shielding portion 53 and be absorbed by the third light-shielding portion 53. As a result, the light leakage at the edge of the optical device E may be effectively ameliorated, and the quality of the images displayed on the display panel 100 is improved.

It should be noted that due to certain uncontrollable deviations (such as manufacturing process deviation, equipment accuracy, etc.), when a floating range of a deviation of the width L2 of the third light-shielding portion 53 is within

$$\\ 5 \% \times ( \frac{D 1 + D 2}{sin α 1 \times cos α 1} - \frac{D 2 \times cos α 1}{sin α 1} ) ,$$

it can be considered that the width L2 of the third light-shielding portion 53 is equal to or approximately equal to

$$\\ \frac{D 1 + D 2}{sin α 1 \times cos α 1} - \frac{D 2 \times cos α 1}{sin α 1} .$$

Other numerical floating ranges of the width L2 of the third light-shielding portion 53 are as above, which will not be repeated here.

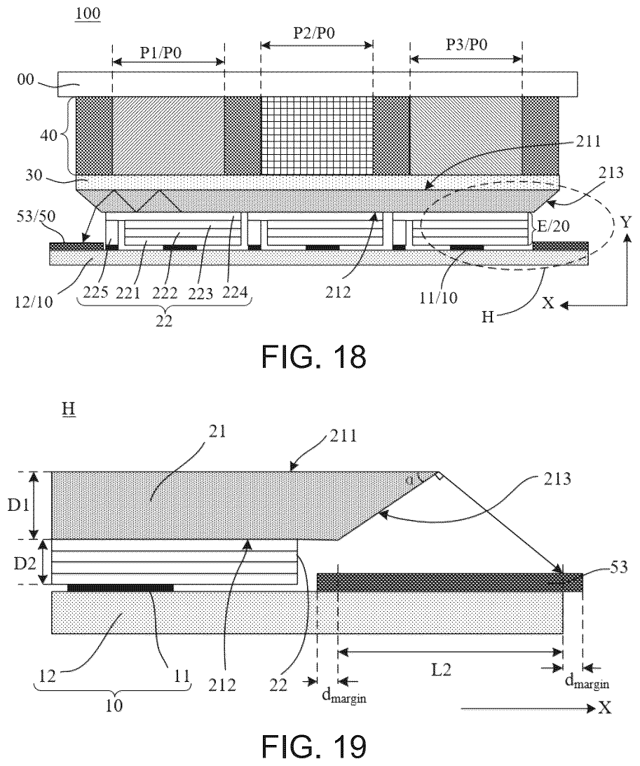

FIG. 18 is a sectional view of yet another display panel, in accordance with some embodiments.

In some embodiments, referring to FIG. 18, the orthographic projection of the part of the third light-shielding portion 53 proximate to the light-emitting unit 22 on the base substrate 12 is located within the orthographic projection of the second surface 212 of the buffer layer 21 on the base substrate 12. That is, the part of the third light-shielding portion 53 proximate to the light-emitting unit 22 may expand slightly toward a center of the optical device E relative to the side surface 213 of the buffer layer 21, so that the outward expanding portion of the third light-shielding portion 53 may absorb the light that is emitted through the side surface 213 and diverges toward the center of the optical device E. Therefore, it may effectively avoid that this part of light is reflected by other structures in the display panel 100 to the outside of the display panel 100, which causes the light leakage at the edge of the optical device E. As a result, it may be conducive to improving the quality of the images displayed on the display panel 100. The embodiments of the present disclosure do not limit the width of the third light-shielding portion 53 expanding toward the center of the optical device E.

In some other embodiments, the boundary of the orthographic projection of the third light-shielding portion 53 on the base substrate 12 exceeds the boundary of the orthographic projection of the first surface 211 on the base substrate 12, and the orthographic projection of the part of the third light-shielding portion 53 proximate to the light-emitting unit 22 on the base substrate 12 is located within the orthographic projection of the second surface 212 of the buffer layer 21 on the base substrate 12. That is, on the basis that the orthographic projection of the third light-shielding portion 53 on the base substrate 12 covers the orthographic projection on the side surface 213 of the base substrate 12, the third light-shielding portion 53 is expanded outward to two sides, so that the third light-shielding portion 53 fully covers the irradiation range of the light emitted toward the driving backplane 10 through the side surface 213, and all the light emitted toward the base substrate 12 through the side surface 213 may be incident on the light-shielding portion 50 and be absorbed by the light-shielding portion 50. Therefore, it may effectively avoid that this part of light is reflected by other structures in the display panel 100 to the outside of the display panel 100, which causes the light leakage at the edge of the optical device E. As a result, it may be conducive to improving the quality of the images displayed on the display panel 100.

FIG. 19 is a partial enlarged view of the region H in FIG. 18.

In some embodiments, referring to FIG. 19, the width L2 of the third light-shielding portion 53 in the first direction X satisfies:

$$\\ L 2 > \frac{D 1 + D 2}{sin α 1 \times cos α 1} - \frac{D 2 \times cos α 1}{sin α 1} + 2 {d}_{margin} .$$

Here, α1 is the value of the first acute angle α, D1 is the thickness of the buffer layer 21, D2 is the thickness of the light-emitting unit 22, d_{margin} is the distance by which the part of the third light-shielding portion 53 expands outward in the first direction X, and the first direction X is parallel to the driving backplane 10.

When the width L2 of the third light-shielding portion 53 is equal to or approaches

$$\\ \frac{D 1 + D 2}{sin α 1 \times cos α 1} - \frac{D 2 \times cos α 1}{sin α 1} + 2 {d}_{margin} ,$$

the third light-shielding portion 53 may be expanded toward two sides in the first direction X, so that the third light-shielding portion 53 fully covers the irradiation range of the light emitted toward the driving backplane 10 through the side surface 213. Therefore, all the light emitted toward the base substrate 12 through the side surface 213 may be incident on the light-shielding portion 50 and be absorbed by the light-shielding portion 50, which ameliorates the light leakage at the edge of the optical device E.

The embodiments of the present disclosure do not specifically limit the magnitude of the distance d_{margin} by which the part of the third light-shielding portion 53 expands outward in the first direction X.

In some embodiments, referring to FIG. 19, the width L2 of the third light-shielding portion 53 in the first direction X satisfies:

$$\\ L 2 = \frac{D 1 + D 2}{sin α 1 \times cos α 1} - \frac{D 2 \times cos α 1}{sin α 1} + 2 {d}_{margin} .$$

In the case where the width L2 of the third light-shielding portion 53 in the first direction X is approximately

$$\\ \frac{D 1 + D 2}{sin α 1 \times cos α 1} - \frac{D 2 \times cos α 1}{sin α 1} + 2 {d}_{margin} ,$$

when the light transmitted in the buffer layer 21 is emitted to the base substrate 12 through the side surface 213, the light may be incident on the third light-shielding portion 53 and be absorbed by the third light-shielding portion 53, so that the influence of the third light-shielding portion 53 on the aperture ratio in the display panel 100 may be reduced to a greatest extent.

It should be noted that due to certain uncontrollable deviations (such as manufacturing process deviation, equipment accuracy, etc.), when a floating range of a deviation of the width L2 of the third light-shielding portion 53 is within

$$\\ 5 \% \times ( \frac{D 1 + D 2}{sin α 1 \times cos α 1} - \frac{D 2 \times cos α 1}{sin α 1} + 2 {d}_{margin} ) ,$$

it can be considered that the width L2 of the third light-shielding portion 53 is equal to or approximately equal to

$$\\ \frac{D 1 + D 2}{sin α 1 \times cos α 1} - \frac{D 2 \times cos α 1}{sin α 1} + 2 {d}_{margin} .$$

Other numerical floating ranges of the width L2 of the third light-shielding portion 53 are as above, which will not be repeated here.

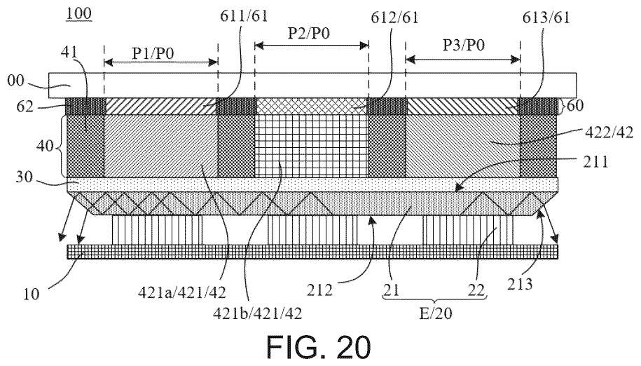

FIG. 20 is a sectional view of yet another display panel, in accordance with some embodiments.

In some embodiments, referring to FIG. 20, the display panel 100 further includes a color filter layer 60. The color filter layer 60 is located on a side of the optical conversion layer 40 away from the driving backplane 10. The color filter layer 60 includes a plurality of filter units 61. An orthographic projection of the filter unit 61 on the driving backplane 10 at least partially overlaps with the orthographic projection of the light-emitting portion 22 on the driving backplane 10. The filter unit 61 may be used to transmit light that is emitted by the light-emitting unit 22 and converted by the corresponding color conversion portion 42.

In some examples, the plurality of filter units 61 include first color filter units 611, second color filter units 612 and third color filter units 613.

The first color filter unit 611 is arranged opposite to the red QD portion 421a, the first color filter unit 611 is located in the first sub-pixel region P1, and the first color filter unit 611 can transmit red light. The second color filter unit 612 is arranged opposite to the green QD portion 421b, the second color filter unit 612 is located in the second sub-pixel region P2, and the second color filter unit 612 can transmit green light. The third color filter unit 613 is arranged opposite to the second-type color conversion portion 422, the third color filter unit 613 is located in the third sub-pixel region P3, and the third color filter unit 613 can transmit blue light.

In some embodiments, with continued reference to FIG. 20, the color filter layer 60 further includes a black matrix 62, and the black matrix 62 separates the plurality of filter units 61. The black matrix 62 may be used to avoid a cross-color problem caused by mutual interference between color light emitted by two adjacent filter units 61.

In some examples, the black matrix 62 is made of a light-shielding material. For example, the black matrix 62 is made of black resin. However, the embodiments of the present disclosure are not limited thereto.

In some embodiments, with continued reference to FIG. 20, the orthographic projection of the color conversion portion 42 on the driving backplane 10 covers the orthographic projection of the filter unit 61 on the driving backplane 10.

A size of the filter unit 61 is slightly smaller than a size of the color conversion portion 42. That is, a size of the black matrix 62 is slightly greater than a size of the blocking portion 41. Therefore, the black matrix 62 may effectively block the light passing through the color conversion portion 42, which avoids the color cast problem caused by the light that passes through the color conversion portion 42 and enters the adjacent filter unit 61.

It can be understood that in some other embodiments, the orthographic projection of the color conversion portion 42 on the driving backplane 10 overlaps with the orthographic projection of the filter unit 61 on the driving backplane 10. In yet some other embodiments, the orthographic projection of the color conversion portion 42 on the driving backplane 10 partially overlaps with the orthographic projection of the filter unit 61 on the driving backplane 10. However, the embodiments of the present disclosure are not limited thereto.

In some embodiments, with continued reference to FIG. 20, the display panel 100 further includes a cover plate 00. The cover plate 00 is located on a side of the color filter layer 60 away from the driving backplane 10. The cover plate 00 may be used to protect film layers below the cover plate 00 from being scratched.

In some examples, a material of the cover plate 00 includes at least one of transparent polyimide and ultra-thin glass. However, the embodiments of the present disclosure are not limited thereto.

In some embodiments, the display panel 100 further includes an encapsulation layer. The encapsulation layer is located on a side of the optical conversion layer 40 away from the color filter layer 60. The encapsulation layer may be used to prevent water and oxygen from corroding both the optical conversion layer and the color filter layer. 60, which may be conducive to prolonging the life of the display panel 100.

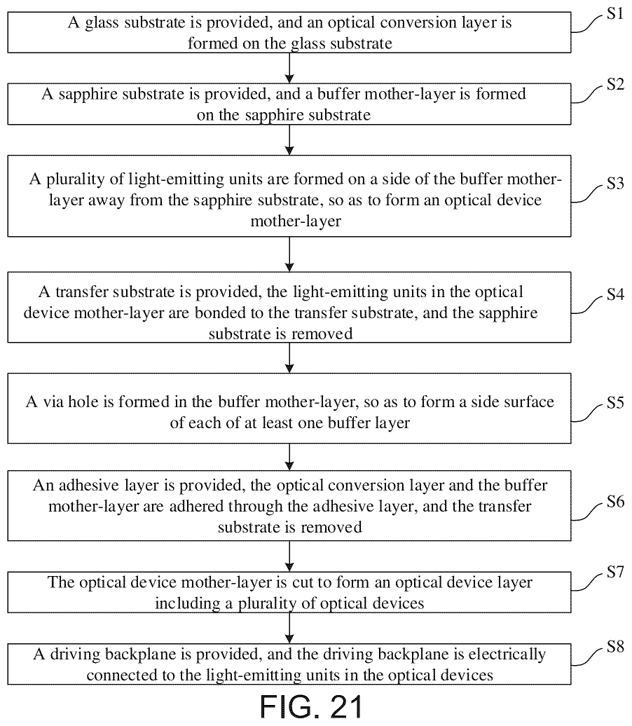

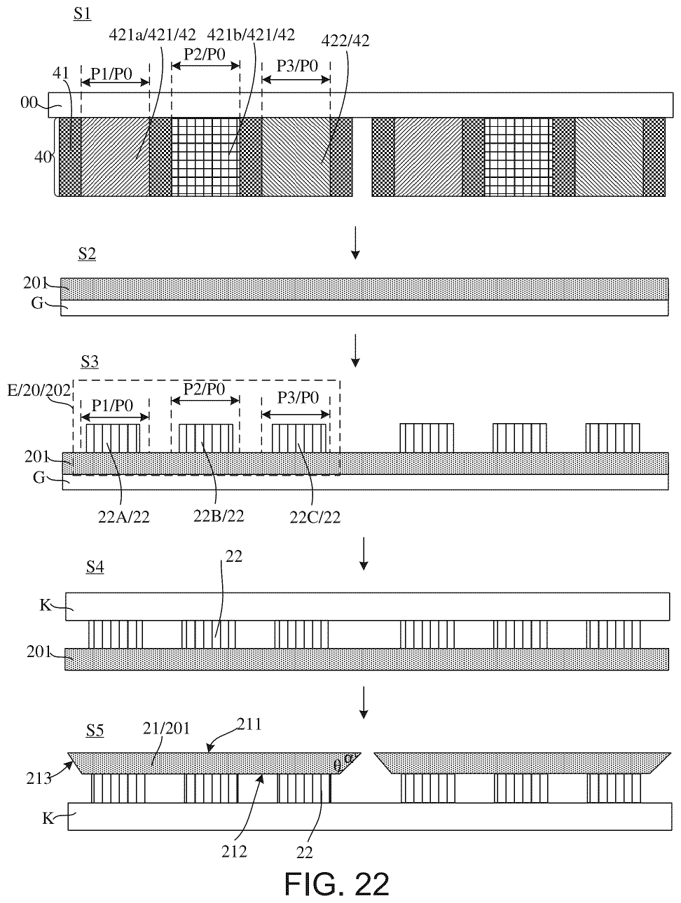

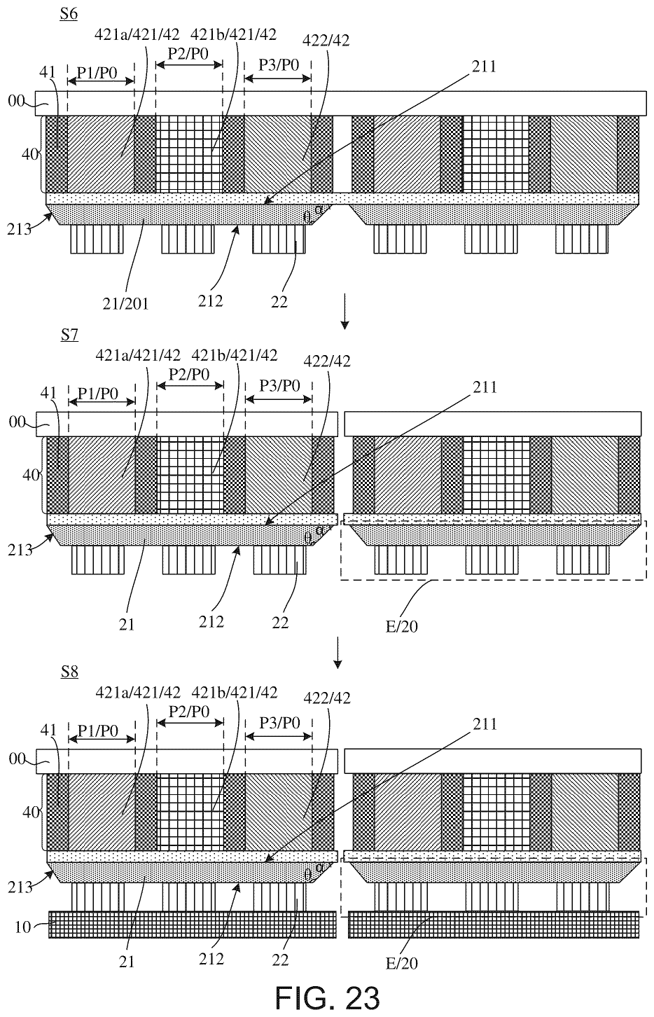

FIG. 21 is a flow diagram of a method of manufacturing a display panel, in accordance with some embodiments. FIG. 22 is a diagram showing structures corresponding to some steps in FIG. 21. FIG. 23 is a diagram showing structures corresponding to some other steps in FIG. 21.

Referring to FIGS. 21 to 23, some embodiments of the present disclosure provide a method of manufacturing a display plane 100. The structure of the display panel 100 may be shown in FIG. 9. The display panel 100 includes a plurality of pixel regions P, and a pixel region P includes a plurality of sub-pixel regions P0. The plurality of sub-pixel regions P0 may include sub-pixel regions P0 that emit light of different colors.

For example, the plurality of sub-pixel regions P0 are divided into first sub-pixel regions P1, second sub-pixel regions P2 and third sub-pixel regions P3. For example, the first sub-pixel regions P1, the second sub-pixel regions P2 and the third sub-pixel regions P3 emit light of three primary colors. For example, the first sub-pixel regions P1 may emit red light, the second sub-pixel regions P2 may emit green light, and the third sub-pixel regions P3 may emit blue light.

The method of manufacturing the display panel 100 includes as follows.

Referring to step S1 shown in FIG. 22, in S1, a glass substrate is provided, and an optical conversion layer 40 is formed on the glass substrate.

In some examples, the glass substrate may be also used as a glass cover plate 00 of the display panel 100. The glass substrate may serve as a base and have a support function to facilitate the fabrication of the optical conversion layer 40 on the glass substrate. After the display panel 100 is manufactured, the glass substrate may be also used as the glass cover plate 00 of the display panel 100, which may protect the display panel 100 and prevent the film layers inside the display panel 100 from being scratched.

Referring to step S2 shown in FIG. 22, in S2, a sapphire substrate G is provided, and a buffer mother-layer 201 is formed on the sapphire substrate G. The buffer mother-layer 201 is used for forming a plurality of buffer layers 21.

In some examples, the material of the buffer mother-layer 201 includes gallium nitride (GaN). However, the embodiments of the present disclosure are not limited thereto.

Referring to step S3 in FIG. 22, in S3, a plurality of light-emitting units 22 are formed on a side of the buffer mother-layer 201 away from the sapphire substrate G to form an optical device mother-layer 202. One light-emitting unit 22 is located in one sub-pixel region P0. At least one light-emitting unit 22 and a buffer layer 21 arranged opposite thereto constitute an optical device E.

In some examples, one light-emitting unit 22 and a buffer layer 21 arranged opposite thereto constitute an optical device E. That is, one optical device E may include one light-emitting unit 22. In this case, one optical device E is located in one sub-pixel region P0. Three optical devices E can be set to be located in one pixel region P.

In some other examples, three light-emitting units 22 and a buffer layer 21 arranged opposite thereto constitute an optical device E. That is, one optical device E may include three light-emitting units 22, and one light-emitting unit 22 is located in one sub-pixel region P0. The three light-emitting units 22 are respectively a first light-emitting unit 22A, a second light-emitting unit 22B and a third light-emitting unit 22C.

In this case, one optical device E is located in one pixel region P. Three light-emitting units 22 in one optical device E may be located in a first sub-pixel region P1, a second sub-pixel region P2 and a third sub-pixel region P3, respectively. For example, the first light-emitting unit 22A is located in the first sub-pixel region P1, the second light-emitting unit 22B is located in the second sub-pixel region P2, and the third light-emitting unit 22C is located in the third sub-pixel region P3.

FIGS. 22 and 23 show an example in which three light-emitting units 22 and the corresponding part of the buffer layer 21 constitute one optical device E.

Referring to step S4 in FIG. 22, in S4, a transfer substrate K is provided, the light-emitting units 22 in the optical device mother-layer 202 are bonded to the transfer substrate K, and the sapphire substrate G is removed.

Referring to step S5 in FIG. 22, in S5, a via hole is formed in the buffer mother-layer 201, so as to form a side surface 213 of each of at least one buffer layer 21. The buffer layer 21 includes a first surface 211 and a second surface 212. The first surface 211 is located on a side of the second surface 212 away from the light-emitting unit 22. The side surface 213 intersects with the first surface 211 to form a first acute angle α, and the side surface 213 intersects with the second surface 212 to form a first obtuse angle θ.

During step S5, a laser sintering process may be used to form the via hole. The via hole is located at the edge of the buffer layer 21 in the at least one optical device E. However, the embodiments of the present disclosure are not limited thereto.

Referring to step S6 in FIG. 23, in S6, an adhesive layer 30 is provided, the optical conversion layer 40 and the buffer mother-layer 201 are adhered through the adhesive layer 30, and the transfer substrate K is removed.

In some examples, the adhesive layer 30 may be a bonding adhesive layer. For example, the adhesive layer 30 may be made of benzocyclobutene (BCB). In this case, the refractive index of the adhesive layer 30 is approximately 1.56. However, the embodiments of the present disclosure are not limited thereto.

Referring to step S7 in FIG. 23, in S7, the optical device mother-layer 202 is cut to form an optical device layer 20 including a plurality of optical devices E.

For example, among the plurality of light-emitting units 22, every three adjacent light-emitting units 22 are assigned to a region for cutting, so that every three light-emitting units 22 constitute an optical device E.

Referring to step S8 in FIG. 23, in S8, a driving backplane 10 is provided, and the driving backplane is electrically connected to the light-emitting units 22 in the optical devices.

In summary, in the method of manufacturing the display panel 100 provided in the embodiments of the present disclosure, during the process of fabricating the optical devices E, an edge of a portion of the buffer mother-layer 201 corresponding to the at least one optical device E may be processed, so that the side surface 213 of the buffer layer 21 in the optical device E is formed, the side surface 213 intersects with the first surface 211 to form the first acute angle α and intersects with the second surface 212 to form the first obtuse angle θ. Based on this, the side surface 213 of the buffer layer 21 in the optical device E may be arranged to face the driving backplane 10, so that an inverted triangle structure may be formed at the edge of the buffer layer 21 in the optical device E. It may be conducive to increasing the probability of light being emitted toward the driving backplane 10 through the side surface 213, and in turn reducing the probability of light being emitted toward the optical conversion layer 40, and ameliorating the problem of light leakage at the edge of the optical device E. As a result, the quality of the display image of the display panel 100 is improved.

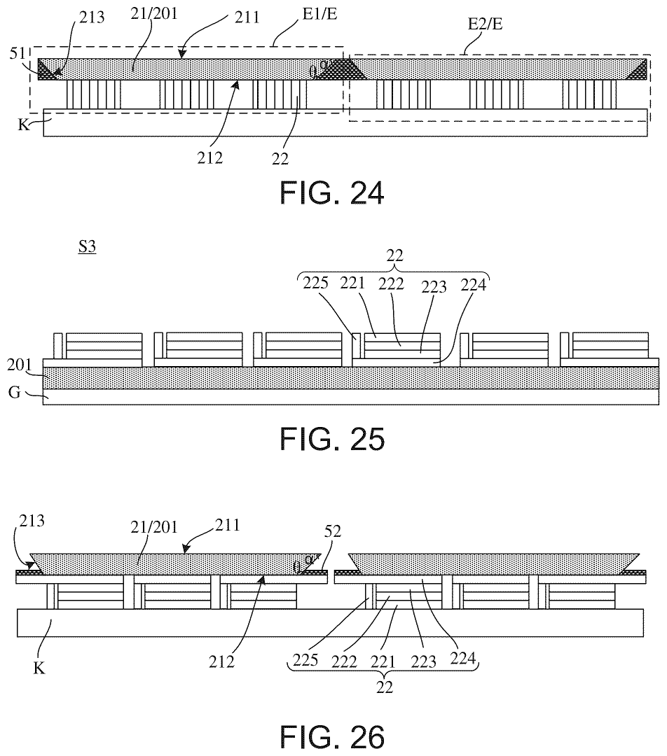

FIG. 24 is a diagram showing a structure corresponding to step S5 in FIG. 21.

In some embodiments, referring to FIG. 24, after step S5 in which the side surface 213 of the buffer layer 21 is formed, a first light-shielding portion 51 is formed on the side surface 213, and an orthographic projection of the first light-shielding portion 51 on the driving backplane 10 covers an orthographic projection of the side surface 213 on the driving backplane 10.

After step S5 in which the via hole is formed through the laser sintering process, the first light-shielding portion 51 may be filled in the via hole, so that the first light-shielding portion 51 is formed on the side surface 213, and the orthographic projection of the first light-shielding portion 51 on the driving backplane 10 covers the orthographic projection of the side surface 213 on the driving backplane 10.

Based on this, when the light transmitted in the buffer layer 21 is emitted from the side surface 213, the light may be incident on the first light-shielding portion 51, and then the light may be blocked and absorbed by the first light-shielding portion 51. Therefore, it may be possible to effectively avoid that the light transmitted in the buffer layer 21 is refracted by the side surface 213 and then directed toward the optical conversion layer 40 and exits the display panel 100, and in turn effectively ameliorate the light leakage at the edge of the optical device E and improve the quality of the images displayed on the display panel 100.

In some embodiments, the first light-shielding portion 51 is made of a light absorption material. For example, the material of the first light-shielding portion 51 adopts at least one of molybdenum, chromium, aluminum, titanium and copper with low reflectivity, or an alloy containing at least one of the above metals, or metal oxide and metal nitride corresponding to any of the above metals. However, the embodiments of the present disclosure are not limited thereto.

In some examples, the first light-shielding portion 51 is formed on the side surface 213 through a sputtering manner. However, the embodiments of the present disclosure are not limited thereto.

Considering an example in which via holes are formed at edges of portions of the buffer mother-layer 201 corresponding to at least two adjacent optical devices E through the laser sintering process in step S5 for illustration, two optical devices E are respectively a first optical device E1 and a second optical device E2.

A via hole, proximate to the second optical device E2, of the buffer layer 21 of the first optical device E1 may be communicated with a via hole, proximate to the first optical device E1, of the buffer layer 21 of the second optical device E2 to form a communication hole. That is, a portion of the buffer mother-layer 201 at a position between the first optical device E1 and the second optical device E2 may be subjected to the laser sintering process to form the communication hole. After the communication hole is formed, a first light-shielding film 501 may be formed in the communication hole, so that two ends of the first light-shielding film 501 are respectively attached to the side surface 213 of the buffer layer 21 of the first optical device E1 proximate to the second optical device E2 and the side surface 213 of the buffer layer 21 of the second optical device E2 proximate to the first optical device E1.

When the optical devices E are subsequently formed by cutting, the first light-shielding film 501 in the communication hole may be divided into two, so that the first light-shielding portion 51 is formed on the side surface 213 of the buffer layer 21 in each optical device E.

FIG. 25 is a diagram showing a structure corresponding to step S3 shown in FIG. 21.

In some embodiments, referring to FIG. 25, step S3 in which the plurality of light-emitting units 22 are formed on the side of the buffer mother-layer away from the sapphire substrate G includes the following steps.

In S31, second semiconductor layers 224 are formed on a side of the buffer mother-layer 201 away from the sapphire substrate G.

In some examples, the second semiconductor layers 224 are made of P—GaN. However, the embodiments of the present disclosure are not limited thereto.

In S32, a light-generating layer 223 is formed on a side of the second semiconductor layer 224 away from the buffer mother-layer 201.

In some examples, the light-generating layer 223 is a multiple quantum well (MQW) layer.

In S33, a first semiconductor layer 222 is formed on a side of the light-generating layer 223 away from the second semiconductor layer 224.

In some examples, the first semiconductor layer 222 is made of N—GaN. However, the embodiments of the present disclosure are not limited thereto.

In S34, a first electrode 221 is formed on a side of the first semiconductor layer 222 away from the light-generating layer 223, and a second electrode 225 is formed on the side of the second semiconductor layer 224 away from the buffer mother-layer 201.

Based on this, the light-emitting unit 22 may include: a first electrode 221, a first semiconductor layer 222 electrically connected to the first electrode 221, a light-generating layer 223, a second semiconductor layer 224, and a second electrode 225 electrically connected to the second semiconductor layer 224.

FIG. 26 is a diagram showing another structure corresponding to step S5 in FIG. 21.

In some embodiments, referring to FIG. 26, after step S5 in which the side surface 213 of the buffer layer 21 is formed, a second light-shielding portion 52 may be formed on a side of the second semiconductor layer 224 away from the second electrode 225, and the second light-shielding portion 52 is arranged along a peripheral direction of the second surface 212.

After step S5 in which the via hole is formed through the laser sintering process, so that the second light-shielding portion 52 is formed on the side, away from the second electrode 225, of a part of the second semiconductor layer 224 exposed by the via hole, and the second light-shielding portion 52 is arranged along the peripheral direction of the second surface 212.

In this way, at least part of the second light-shielding portion 52 may be located between the side surface 213 and the driving backplane 10. Based on this, when the light transmitted in the buffer layer 21 is refracted by the side surface 213 and then emitted toward the driving backplane 10, at least part of the light may be incident on the second light-shielding portion 52 and absorbed by the second light-shielding portion 52. Therefore, it may be possible to effectively avoid that the part of light is reflected by other structures in the display panel 100 to the outside of the display panel 100, causing the light leakage at the edge of the optical device E. As a result, it may be conducive to improving the quality of the images displayed on the display panel 100.

In some examples, the second light-shielding portion 52 is made of a light-absorbing material. For example, the material of the second light-shielding portion 52 adopts at least one of molybdenum, chromium, aluminum, titanium and copper with low reflectivity, or an alloy containing at least one of the above metals, or metal oxide and metal nitride corresponding to any of the above metals. However, the embodiments of the present disclosure are not limited thereto.

In some embodiments, the first light-shielding portion 51 and the second light-shielding portion 52 may be provided in the display panel 100 at the same time. The embodiments of the present disclosure are not limited thereto.

The second light-shielding portion 52 may be formed on the side of the second semiconductor layer 224 away from the second electrode 225, and then the first light-shielding portion 51 may be formed on the side surface 213. It can be understood that in some other embodiments, the first light-shielding portion 51 is formed, and then the second light-shielding portion 52 is formed, which is not limited in the present disclosure.

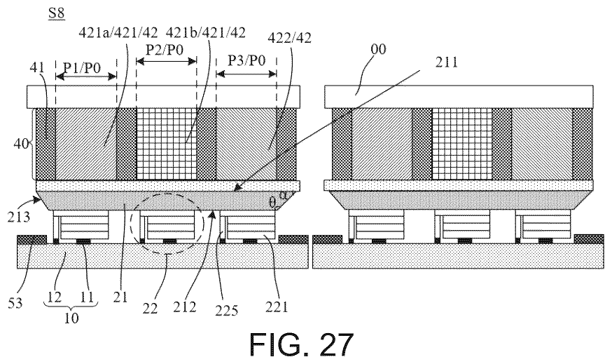

FIG. 27 is a diagram showing a structure corresponding to the step S8 in FIG. 21.

In some embodiments, referring to FIG. 27, the driving backplane 10 provided in step S8 may include a base substrate 12 and a plurality of connection electrodes 11 located on the base substrate 12. The driving backplane 10 is electrically connected to the light-emitting units 22 through the connection electrodes 11.

For example, a connection electrode of the plurality of connection electrodes 11 is electrically connected to the first electrode 221 in the light-emitting unit 22, and another connection electrode of the plurality of connection electrodes 11 is electrically connected to the second electrode 225 in the light-emitting unit 22, so that the light-emitting unit 22 is electrically connected to the driving backplane 10. Thus, the driving backplane 10 drives the light-emitting unit 22 to emit light.

In some examples, the base substrate 12 may be a flexible base. For example, the base substrate 12 is made of an organic material. For example, the base substrate 12 is made of any one of polyimide (PI), polycarbonate (PC) or polyvinyl chloride (PVC).

In some other examples, the base substrate 12 is a rigid base. For example, the rigid base is a glass base or a polymethyl methacrylate (PMMA) base.

In some embodiments, the driving backplane 10 further includes a driving circuit layer. The driving circuit layer may be located between the base substrate 12 and the connection electrodes 11. The driving circuit layer is used to control the connection electrodes 11 to transmit electrical signals to first electrodes 221 and second electrodes 225 in the light-emitting units 22, so as to drive the light-emitting units 22 to emit light.

In some embodiments, with continued reference to FIG. 27, after the driving backplane is electrically connected to the light-emitting units 22 in the optical devices in step S8, a third light-shielding portion 53 may be formed on the base substrate 12, and an orthographic projection of the third light-shielding portion 53 on the base substrate 12 is arranged along a peripheral direction of the orthographic projection of the second surface 212 on the base substrate 12.

Based on this, when the light transmitted in the buffer layer 21 is refracted by the side surface 213 and then emitted toward the driving backplane 10, at least part of the light may be incident on the third light-shielding portion 53 and absorbed by the third light-shielding portion 53. Therefore, it may be possible to effectively avoid that the part of light is reflected by other structures in the display panel 100 to the outside of the display panel 100, causing the light leakage at the edge of the optical device E. As a result, it may be conducive to improving the quality of the images displayed on the display panel 100.

In some examples, the third light-shielding portion 53 is made of a light-absorbing material. For example, the material of the third light-shielding portion 53 adopts at least one of molybdenum, chromium, aluminum, titanium and copper with low reflectivity, or an alloy containing at least one of the above metals, or metal oxide and metal nitride corresponding to any of the above metals. However, the embodiments of the present disclosure are not limited thereto.

In some embodiments, the display panel 100 may include both the first light-shielding portion 51 and the third light-shielding portion 53. In some other embodiments, the display panel 100 may include both the second light-shielding portion 52 and the third light-shielding portion 53. In yet some other embodiments, the display panel 100 may include the first light-shielding portion 51, the second light-shielding portion 52 and the third light-shielding portion 53. However, the embodiments of the present disclosure do not specifically limit the order in which the first light-shielding portion 51, the second light-shielding portion 52 and the third light-shielding portion 53 are formed.

The foregoing descriptions are merely specific implementation manners of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

What is claimed is:

1. A display panel, having a plurality of sub-pixel regions, the display panel comprising:
a driving backplane;
an optical device layer located on a side of the driving backplane, the optical device layer including a plurality of optical devices, wherein
each of the plurality of optical devices includes:
a buffer layer including a first surface and a second surface, the first surface being farther away from the driving backplane than the second surface; and
at least one light-emitting unit located on a side of the second surface away from the first surface, one of the at least one light-emitting unit being located in one of the plurality of sub-pixel regions, wherein
a buffer layer of an optical device of at least one of the plurality of optical devices further includes a side surface, the side surface intersects with a first surface of the buffer layer of the optical device to form a first acute angle, and the side surface intersects with a second surface of the buffer layer of the optical device to form a first obtuse angle;
an optical conversion layer located on a side of the optical device layer away from the driving backplane; and
an adhesive layer located between the buffer layer of each of the plurality of optical devices in the optical device layer and the optical conversion layer, wherein the adhesive layer is in contact with the first surface of the buffer layer of each of the plurality of optical devices, and a refractive index of the adhesive layer is less than a refractive index of the buffer layer of each of the plurality of optical devices.

2. The display panel according to claim 1, wherein a value α1 of the first acute angle satisfies:
$$\\ α 1 < 90 ° - arc sin \frac{1}{n 1} ;$$
wherein n1 is the refractive index of the buffer layer.

3. The display panel according to claim 1, further comprising a light-shielding portion located on a side of the first surface of the buffer layer of the optical device proximate to the driving backplane, an orthographic projection of the light-shielding portion on the driving backplane at least partially overlapping with an orthographic projection of the side surface on the driving backplane.

4. The display panel according to claim 3, wherein the light-shielding portion includes a first light-shielding portion, the first light-shielding portion is located on the side surface, and the first light-shielding portion is in contact with the side surface.

5. The display panel according to claim 4, wherein a surface of the first light-shielding portion proximate to the driving backplane is flush with the second surface of the buffer layer of the optical device; and/or
in a first direction, an orthographic projection of a surface of the first light-shielding portion away from the buffer layer of the optical device on the driving backplane overlaps with a boundary of an orthographic projection of the first surface of the buffer layer of the optical device on the driving backplane, the first direction being parallel to the driving backplane.

6. The display panel according to claim 3, wherein in a direction away from the driving backplane, each of the at least one light-emitting unit includes: a first electrode, a first semiconductor layer electrically connected to the first electrode, a light-generating layer, and a second semiconductor layer; each of the at least one light-emitting unit further includes: a second electrode electrically connected to the second semiconductor layer; the second electrode is located on a side of the second semiconductor layer proximate to the driving backplane;
the light-shielding portion further includes a second light-shielding portion, and the second light-shielding portion is located on a side of a second semiconductor layer in a light-emitting unit of the optical device away from a second electrode in the light-emitting unit of the optical device.

7. The display panel according to claim 6, wherein a part of the second light-shielding portion proximate to the buffer layer of the optical device is in contact with a part of the side surface of the buffer layer of the optical device proximate to the second surface of the buffer layer of the optical device; and/or
a boundary of an orthographic projection of the second light-shielding portion on the driving backplane exceeds a boundary of an orthographic projection of the first surface of the buffer layer of the optical device on the driving backplane.

8. The display panel according to claim 7, wherein a width L1 of the second light-shielding portion in a first direction satisfies:
$$\\ L 1 = \frac{D 1}{sin α 1 \times cos α 1} ;$$
wherein α1 is a value of the first acute angle, D1 is a thickness of the buffer layer of the optical device, and the first direction is parallel to the driving backplane.

9. The display panel according to claim 3, wherein the driving substrate includes a base substrate and a plurality of connection electrodes located on the base substrate; connection electrodes among the plurality of connection electrodes are electrically connected to a light-emitting unit;
the light-shielding portion further includes a third light-shielding portion, and the third light-shielding portion is located on a side of the base substrate proximate to the buffer layer of the optical device.

10. The display panel according to claim 9, wherein an orthographic projection, on the base substrate, of a part of the third light-shielding portion proximate to a light-emitting unit in the optical device is in contact with a boundary of an orthographic projection, on the base substrate, of the second surface of the buffer layer of the optical device;
a boundary of an orthographic projection of the third light-shielding portion on the base substrate exceeds a boundary of an orthographic projection of the first surface of the buffer layer of the optical device on the base substrate.

11. The display panel according to claim 10, wherein a width L2 of the third light-shielding portion in a first direction satisfies:
$$\\ L 2 = \frac{D 1 + D 2}{sin α 1 \times cos α 1} - \frac{D 2 \times cos α 1}{sin α 1} ;$$
wherein α1 is a value of the first acute angle, D1 is a thickness of the buffer layer of the optical device, D2 is a thickness of the light-emitting unit in the optical device, and the first direction is parallel to the driving backplane.

12. The display panel according to claim 1, wherein the optical conversion layer includes a blocking portion and a plurality of color conversion portions; the blocking portion separates the plurality of color conversion portions;
an orthographic projection of a color conversion portion on the driving backplane at least partially overlaps with an orthographic projection of a light-emitting unit corresponding to the color conversion portion on the driving backplane;
the color conversion portions include a first-type color conversion portion and a second-type color conversion portion; the first-type color conversion portion is configured to convert a color of light emitted by a light-emitting unit corresponding to the first-type color conversion portion into a target color; and the second-type color conversion portion is configured to directly transmit light emitted by a light-emitting unit corresponding to the second-type color conversion portion.

13. The display panel according to claim 12, wherein the orthographic projection of the color conversion portion on the driving backplane covers the orthographic projection of the light-emitting unit corresponding to the color conversion portion on the driving backplane.

14. The display panel according to claim 12, further comprising a color filter layer located on a side of the optical conversion layer away from the driving backplane, wherein the color filter layer includes a plurality of filter units and a black matrix; the black matrix separates the plurality of the filter units;
an orthographic projection of a filter unit on the driving backplane at least partially overlaps with an orthographic projection of a light-emitting unit corresponding to the filter unit on the driving backplane.

15. The display panel according to claim 14, wherein the orthographic projection of the filter unit on the driving backplane covers the orthographic projection of the light-emitting unit corresponding to the filter unit on the driving backplane.

16. A method of manufacturing a display panel, the display panel having a plurality of sub-pixel regions, the method comprising:
providing a glass substrate;
forming an optical conversion layer on the glass substrate;
providing a sapphire substrate;
forming a buffer mother-layer on the sapphire substrate, the buffer mother-layer being used for forming a plurality of buffer layers, each of the plurality of buffer layers including a first surface and a second surface;
forming a plurality of light-emitting units on a side of the buffer mother-layer away from the sapphire substrate, so as to form an optical device mother-layer, wherein one of the light-emitting units is located in one of the sub-pixel regions;
providing a transfer substrate;
bonding the plurality of light-emitting units in the optical device mother-layer to the transfer substrate;
removing the sapphire substrate;
forming a via hole in the buffer mother-layer, so as to form a side surface of each of at least one buffer layer of the plurality of buffer layers, wherein the side surface intersects with a first surface of each of the at least one buffer layer to form a first acute angle, and the side surface intersects with a second surface of each of the at least one buffer layer to form a first obtuse angle;
providing an adhesive layer;
adhering the optical conversion layer and the buffer mother-layer through the adhesive layer;
removing the transfer substrate;
cutting the optical device mother-layer to form an optical device layer including a plurality of optical devices, wherein at least one light-emitting unit of the plurality of light-emitting units and a buffer layer arranged opposite thereto constitute an optical device; and in the optical device, the first surface of the buffer layer is disposed on a side of the second surface away from the at least one light-emitting unit;
providing a driving backplane; and
electrically connecting the driving backplane and the plurality of light-emitting units in the plurality of optical devices.

17. The method according to claim 16, further comprising: forming a first light-shielding portion on the side surface, an orthographic projection of the first light-shielding portion on the driving backplane covering an orthographic projection of the side surface on the driving backplane.

18. The method according to claim 16, wherein in a direction away from the driving backplane, a light-emitting unit includes: a first electrode, a first electrode, a first semiconductor layer electrically connected to the first electrode, a light-generating layer, a second semiconductor layer; and the light-emitting unit further includes a second electrode electrically connected to the second semiconductor layer;
the method further comprises:
forming a second light-shielding portion on a side, away from the second electrode, of a part of the second semiconductor layer exposed by the via hole, the second light-shielding portion being arranged along a peripheral direction of a second surface.

19. The method according to claim 16, wherein the driving backplane includes a base substrate and a plurality of connection electrodes located on the base substrate; connection electrodes among the plurality of connection electrodes are electrically connected to a light-emitting unit;
the method further comprises: after the connection electrodes in the driving backplane are electrically connected to the light-emitting unit, forming a third light-shielding portion on the base substrate, wherein an orthographic projection of the third light-shielding portion on the base substrate is arranged along a peripheral direction of an orthographic projection of a second surface on the base substrate.

20. A display apparatus, comprising the display panel according to claim 1.
